(19) United States
(12) Patent Application Publication
(10) Pub. No.: US 2026/0090119 A1
(43) Pub. Date: Mar. 26, 2026

(54) SOLID-STATE IMAGING DEVICE

(71) Applicant: SONY SEMICONDUCTOR SOLUTIONS CORPORATION, KANAGAWA (JP)

(72) Inventor: KOICHI TAKEUCHI, KANAGAWA (JP)

(21) Appl. No.: 19/109,847

(22) PCT Filed: Aug. 22, 2023
(86) PCT No.: PCT/JP2023/030152

§ 371 Date: Mar. 7, 2025

(30) Foreign Application Priority Data
Sep. 16, 2022 (JP) 2022-148050

(51) Int. Cl. H10F 39/00

(52) U.S. Cl. CPC H10F 39/8063; H10F 39/8053; H10F 39/807

(57) ABSTRACT

The present technology provides a solid-state imaging device capable of suppressing reflection of light at an upper portion of a separation wall.

The solid-state imaging device according to the present technology includes a pixel that includes: first and second light receiving units that are adjacent to each other and receive light in a same wavelength band; and a separation wall provided between the first and second light receiving units. The first light receiving unit includes: a first photoelectric conversion element; and a first phase imparting structure that is provided on an incident side of the light of the first photoelectric conversion element and imparts a first phase to incident light. The second light receiving unit includes: a second photoelectric conversion element; and a second phase imparting structure that is provided on an incident side of the light of the second photoelectric conversion element and imparts a second phase different from the first phase to incident light.

### TECHNICAL FIELD

The technology according to the present disclosure (hereinafter also referred to as the “present technology”) relates to a solid-state imaging device.

### BACKGROUND ART

A conventional solid-state imaging device includes a pixel having a plurality of light receiving units that also performs imaging and phase difference detection (see, for example, Patent Document 1).

In this solid-state imaging device, a separation wall is provided between light receiving units adjacent to each other, and light in the same wavelength band is received for each light receiving unit.

### CITATION LIST

### Patent Document

Patent Document 1: Japanese Patent Application Laid-Open No. 2021-044582

### SUMMARY OF THE INVENTION

### Problems to be Solved by the Invention

However, in the conventional solid-state imaging device, there is room for improvement in suppressing reflection of light at the upper portion of the separation wall.

Therefore, a main object of the present technology is to provide a solid-state imaging device capable of suppressing reflection of light at the upper portion of the separation wall.

### Solutions to Problems

The present technology provides a solid-state imaging device, including:
a pixel that includes:
first and second light receiving units that are adjacent to each other and receive light in a same wavelength band; and
a separation wall provided between the first and second light receiving units, in which
the first light receiving unit includes:
a first photoelectric conversion element; and
a first phase imparting structure that is provided on an incident side of the light of the first photoelectric conversion element and imparts a first phase to incident light, and
the second light receiving unit includes:
a second photoelectric conversion element; and
a second phase imparting structure that is provided on an incident side of the light of the second photoelectric conversion element and imparts a second phase different from the first phase to incident light.

The separation wall may be provided at least between the first and second photoelectric conversion elements, and the first and second phase imparting structures may be located on an incident side of the light of the separation wall.

An absolute value of a phase difference between the first and second phases may be a value of (Nπ−π/2) or more and (Nπ+π/2) or less, where N is an odd number.

The first and second photoelectric conversion elements may be provided side by side in an in-plane direction in a semiconductor substrate. The first phase imparting structure may include: a first portion that is a portion having a refractive index different from a refractive index of the semiconductor substrate and is provided on a surface of the semiconductor substrate on an incident side of the light; and a second portion that is a part of the semiconductor substrate and is located on a side opposite to an incident side of the light of the first portion. The second phase imparting structure may be provided on a surface of the semiconductor substrate on an incident side of the light. Surfaces of the first portion and the second phase imparting structure on an incident side of the light may be flush.

With respect to a refractive index n₁ of the first portion, a thickness d₁, a refractive index n₂ of the second phase imparting structure, and a thickness d₂ (≥d₁), a refractive index nₛ of the semiconductor substrate, and a wavelength λ of the light, (Nλ/2−λ/4)≤|n₁d₁+nₛ (d₂−d₁)−n₂d₂|≤(Nλ/2+λ/4) may be satisfied, where N is an odd number.

The first and second photoelectric conversion elements may be provided side by side in an in-plane direction in a semiconductor substrate. An insulating film may be provided on an incident side of the light of the semiconductor substrate. The first phase imparting structure may include: a first portion that is a portion having a refractive index different from a refractive index of the insulating film and is provided on a surface of the semiconductor substrate on an incident side of the light; and a second portion that is a part of the insulating film and is located on an incident side of the light of the first portion. The second phase imparting structure may be provided between the semiconductor substrate and the insulating film. Surfaces of the first portion and the second phase imparting structure on a side opposite to an incident side of the light may be flush.

With respect to a refractive index n₁ of the first portion, a thickness d₁, a refractive index n₂ of the second phase imparting structure, and a thickness d₂ (≥d₁), a refractive index n₁ of the insulating film, and a wavelength λ of the light, (Nλ/2−λ/4)≤|n₁d₁+n₁ (d₂−d₁)−n₂d₂|≤(Nλ/2+λ/4) may be satisfied, where N is an odd number.

The first phase imparting structure may have a plurality of first microstructures. The second phase imparting structure may have a plurality of second microstructures.

The plurality of first microstructures may include first and second types of first microstructures having different refractive indexes, the first and second types of first microstructures being alternately arranged in an in-plane direction. The plurality of second microstructures may include first and second types of second microstructures having different refractive indexes, the first and second types of second microstructures being alternately arranged in an in-plane direction.

A ratio of a sum of volumes of the first type of first microstructures and a sum of volumes of the second type of first microstructures may be different from a ratio of a sum of volumes of the first type of second microstructures and a sum of volumes of the second type of second microstructures.

A longitudinal section of at least one of the first or second microstructure may have a tapered shape.

At least one of the first and second phase imparting structures may have an antireflection function of preventing reflection of the light.

The pixel may include an antireflection structure that is arranged on an incident side of the light of the first and second phase imparting structures and prevents reflection of the light.

Light receiving areas of the first and second light receiving units may be different.

The first and second photoelectric conversion elements may be provided side by side in an in-plane direction in a semiconductor substrate. The pixel may include an insulating film disposed between the first and second phase imparting structures and the semiconductor substrate.

The first light receiving unit may further include the second phase imparting structure adjacent to the first phase imparting structure. The light via the second phase imparting structure of the first light receiving unit may be also incident on the first photoelectric conversion element. The second light receiving unit may further include the first phase imparting structure adjacent to the second phase imparting structure. The light via the first phase imparting structure of the second light receiving unit may be also incident on the second photoelectric conversion element. In the pixel, the first and second phase imparting structures may be alternately arranged with respect to first and second directions orthogonal to each other in a plane.

The pixel may include a plurality of the first and second light receiving units. In the pixel, the first and second light receiving units may be alternately arranged in first and second directions orthogonal to each other in a plane.

Other pixels that are adjacent to each other and include a plurality of light receiving units that receives light in a same wavelength band may be further included.

The pixel may include a color filter provided on an incident side of the light of the first and second light receiving units and having the wavelength band as a transmission wavelength band.

The pixel may include a microlens provided on an incident side of the light of the color filter.

### BRIEF DESCRIPTION OF DRAWINGS

FIG. 1 is a diagram schematically illustrating a cross-sectional configuration of a solid-state imaging device according to Example 1 of an embodiment of the present technology.

FIG. 2 is a diagram for explaining an operation at the time of imaging of the solid-state imaging device in FIG. 1.

FIG. 3 is a diagram for explaining an action (part 1) at the time of phase difference detection of the solid-state imaging device in FIG. 1.

FIG. 4 is a diagram for explaining an action (part 2) at the time of phase difference detection of the solid-state imaging device in FIG. 1.

FIG. 5 is a diagram illustrating an intensity distribution for each incident angle of incident light incident on first and second light receiving units of the solid-state imaging device in FIG. 1.

FIG. 6 is a diagram schematically illustrating a cross-sectional configuration of a solid-state imaging device according to Example 2 of an embodiment of the present technology.

FIG. 7 is a diagram schematically illustrating a cross-sectional configuration of a solid-state imaging device according to Example 3 of an embodiment of the present technology.

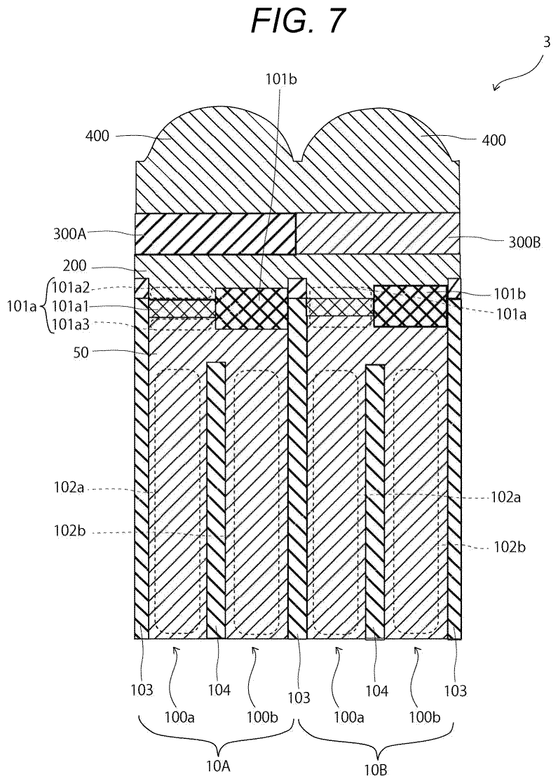

FIG. 8 is a diagram schematically illustrating a cross-sectional configuration of a solid-state imaging device according to Example 4 of an embodiment of the present technology.

FIG. 9 is a diagram schematically illustrating a planar configuration of a solid-state imaging device according to Example 5 of an embodiment of the present technology.

FIG. 10A is a diagram schematically illustrating a cross section taken along line 10A-10A in FIG. 9. FIG. 10B is a diagram schematically illustrating a cross section taken along line 10B-10B in FIG. 9.

FIG. 11 is a graph illustrating a relationship between an incident angle of light on first and second phase imparting structures and a light absorption amount.

FIG. 12 is a diagram schematically illustrating a planar configuration of a solid-state imaging device according to Example 6 of an embodiment of the present technology.

FIG. 13A is a diagram schematically illustrating a cross section taken along line 13A-13A in FIG. 12. FIG. 13B is a diagram schematically illustrating a cross section taken along line 13B-13B in FIG. 12.

FIG. 14 is a diagram illustrating an intensity distribution for each incident angle of incident light incident on the first and second light receiving units of the solid-state imaging device in FIG. 12.

FIG. 15 is a diagram schematically illustrating a planar configuration of a solid-state imaging device according to Example 7 of an embodiment of the present technology.

FIG. 16A is a diagram schematically illustrating a cross section taken along line 16A-16A in FIG. 15. FIG. 16B is a diagram schematically illustrating a cross section taken along line 16B-16B in FIG. 15.

FIG. 17A is a diagram schematically illustrating a cross section taken along line 17A-17A in FIG. 15. FIG. 17B is a diagram schematically illustrating a cross section taken along line 17B-17B in FIG. 15.

FIG. 18A is a diagram schematically illustrating a cross section taken along line 18A-18A in FIG. 15. FIG. 18B is a diagram schematically illustrating a cross section taken along line 18B-18B in FIG. 15.

FIG. 19A is a diagram schematically illustrating a cross section taken along line 19A-19A in FIG. 15. FIG. 19B is a diagram schematically illustrating a cross section taken along line 19B-19B in FIG. 15.

FIG. 20 is a diagram schematically illustrating a cross-sectional configuration of a solid-state imaging device according to Example 8 of an embodiment of the present technology.

FIG. 21 is a flowchart for explaining an example of a method for manufacturing the solid-state imaging device in FIG. 20.

FIGS. 22A and 22B are a schematic plan view and a schematic cross-sectional view, respectively, for each process of the example of the method for manufacturing the solid-state imaging device in FIG. 20.

FIGS. 23A and 23B are a schematic plan view and a schematic cross-sectional view, respectively, for each process of an example of the method for manufacturing the solid-state imaging device in FIG. 20.

FIGS. 24A and 24B are a schematic plan view and a schematic cross-sectional view, respectively, for each process of an example of the method for manufacturing the solid-state imaging device in FIG. 20.

FIGS. 25A and 25B are a schematic plan view and a schematic cross-sectional view, respectively, for each process of an example of the method for manufacturing the solid-state imaging device in FIG. 20.

FIGS. 26A and 26B are a schematic plan view and a schematic cross-sectional view, respectively, for each process of an example of the method for manufacturing the solid-state imaging device in FIG. 20.

FIGS. 27A and 27B are a schematic plan view and a schematic cross-sectional view, respectively, for each process of an example of the method for manufacturing the solid-state imaging device in FIG. 20.

FIGS. 28A and 28B are a schematic plan view and a schematic cross-sectional view, respectively, for each process of an example of the method for manufacturing the solid-state imaging device in FIG. 20.

FIGS. 29A and 29B are a schematic plan view and a schematic cross-sectional view, respectively, for each process of an example of the method for manufacturing the solid-state imaging device in FIG. 20.

FIGS. 30A and 30B are a schematic plan view and a schematic cross-sectional view, respectively, for each process of an example of the method for manufacturing the solid-state imaging device in FIG. 20.

FIGS. 31A and 31B are a schematic plan view and a schematic cross-sectional view, respectively, for each process of an example of the method for manufacturing the solid-state imaging device in FIG. 20.

FIGS. 32A and 32B are a schematic plan view and a schematic cross-sectional view, respectively, for each process of an example of the method for manufacturing the solid-state imaging device in FIG. 20.

FIG. 33 is a diagram schematically illustrating a cross-sectional configuration of a solid-state imaging device according to Example 9 of an embodiment of the present technology.

FIG. 34 is a diagram schematically illustrating a cross-sectional configuration of a solid-state imaging device according to Example 10 of an embodiment of the present technology.

FIG. 35 is a diagram schematically illustrating a planar configuration of a solid-state imaging device according to Example 11 of an embodiment of the present technology.

FIG. 36A is a diagram schematically illustrating a cross section taken along line 36A-36A in FIG. 35. FIG. 36B is a diagram schematically illustrating a cross section taken along line 36B-36B in FIG. 35.

FIG. 37A is a diagram schematically illustrating a cross section taken along line 37A-37A in FIG. 35. FIG. 37B is a diagram schematically illustrating a cross section taken along line 37B-37B in FIG. 35.

FIG. 38A is a diagram schematically illustrating a cross section taken along line 38A-38A in FIG. 35. FIG. 38B is a diagram schematically illustrating a cross section taken along line 38B-38B in FIG. 35.

FIG. 39A is a diagram schematically illustrating a cross section taken along line 39A-39A in FIG. 35. FIG. 39B is a diagram schematically illustrating a cross section taken along line 39B-39B in FIG. 35.

FIG. 40 is a diagram schematically illustrating a planar configuration of a solid-state imaging device according to Example 12 of an embodiment of the present technology.

FIG. 41 is a diagram schematically illustrating a cross-sectional configuration of a solid-state imaging device according to Example 13 of an embodiment of the present technology.

FIG. 42 is a diagram schematically illustrating a cross-sectional configuration of a solid-state imaging device according to Example 14 of an embodiment of the present technology.

FIG. 43 is a diagram schematically illustrating a cross-sectional configuration of a solid-state imaging device according to Example 15 of an embodiment of the present technology.

FIG. 44 is a diagram schematically illustrating a cross-sectional configuration of a solid-state imaging device according to a modification of Example 1 of an embodiment of the present technology.

FIG. 45 is a diagram schematically illustrating a cross-sectional configuration of a solid-state imaging device according to a modification of Example 2 of an embodiment of the present technology.

FIG. 46 is a diagram schematically illustrating a cross-sectional configuration of a solid-state imaging device according to a modification of Example 3 of an embodiment of the present technology.

FIG. 47 is a diagram schematically illustrating a cross-sectional configuration of a solid-state imaging device of a comparative example.

FIGS. 48A and 48B each are diagrams illustrating intensity distributions for each incident angle of incident light incident on first and second photodiodes of the solid-state imaging device in FIG. 47.

FIG. 49 is a diagram illustrating a usage example of a solid-state imaging device to which the present technology is applied.

FIG. 50 is a functional block diagram of an example of an electronic apparatus including a solid-state imaging device to which the present technology is applied.

FIG. 51 is a block diagram illustrating an example of a schematic configuration of a vehicle control system.

FIG. 52 is an explanatory diagram illustrating an example of installation positions of a vehicle exterior information detection unit and an image pickup unit.

FIG. 53 is a diagram illustrating an example of a schematic configuration of an endoscopic surgery system.

FIG. 54 is a block diagram illustrating an example of functional configurations of a camera head and a CCU.

### MODE FOR CARRYING OUT THE INVENTION

Hereinafter, preferred embodiments of the present technology will be described in detail with reference to the accompanying drawings. Note that, in the present specification and the drawings, components having substantially the same functional configurations are denoted by the same reference signs, and redundant descriptions are omitted. The embodiments to be described below provide representative embodiments of the present technology, and the scope of the present technology is not to be narrowly interpreted according to those embodiments.

In the present specification, even in a case where a solid-state imaging device according to the present technology each exert a plurality of effects, each of the solid-state imaging devices according to the present technology is only required to exert at least one of the effects. The effects described in the present specification are merely examples and are not limited, and other effects may be exerted.

Furthermore, the description will be given in the following order.
0. Introduction
1. Solid-state imaging device according to Example 1 of an embodiment of the present technology
2. Solid-state imaging device according to Example 2 of an embodiment of the present technology
3. Solid-state imaging device according to Example 3 of an embodiment of the present technology
4. Solid-state imaging device according to Example 4 of an embodiment of the present technology
5. Solid-state imaging device according to Example 5 of an embodiment of the present technology
6. Solid-state imaging device according to Example 6 of an embodiment of the present technology
7. Solid-state imaging device according to Example 7 of an embodiment of the present technology
8. Solid-state imaging device according to Example 8 of an embodiment of the present technology
9. Solid-state imaging device according to Example 9 of an embodiment of the present technology
10. Solid-state imaging device according to Example 10 of an embodiment of the present technology
11. Solid-state imaging device according to Example 11 of an embodiment of the present technology
12. Solid-state imaging device according to Example 12 of an embodiment of the present technology
13. Solid-state imaging device according to Example 13 of an embodiment of the present technology
14. Solid-state imaging device according to Example 14 of an embodiment of the present technology
15. Solid-state imaging device according to Example 15 of an embodiment of the present technology
16. Modifications of the present technology
17. Usage example of solid-state imaging device to which the present technology is applied
18. Other usage examples of solid-state imaging device to which the present technology is applied
19. Application example to mobile body
20. Application example to endoscopic surgery system

### 0. Introduction

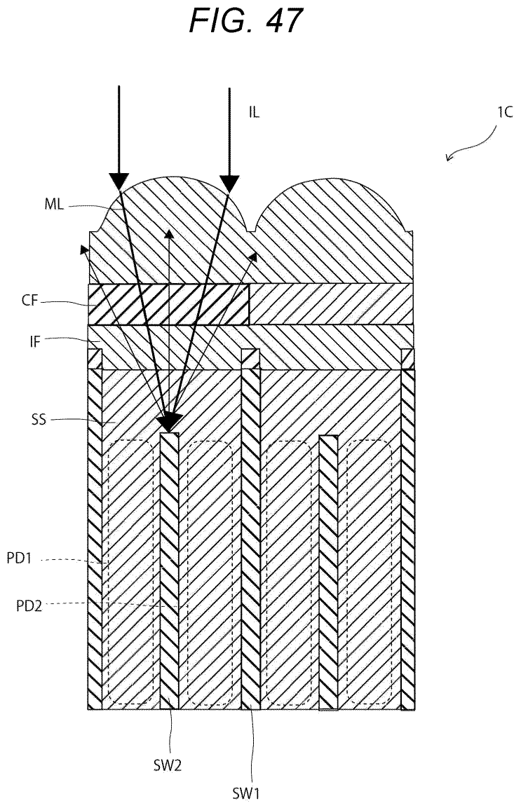

In recent years, in a solid-state imaging device (image sensor), an auto focus (AF) function using an image plane phase difference, so-called image plane phase difference AF, has become widespread. As a method of the image plane phase difference AF, there is a dual pixel method in which all or many pixels serve both imaging and phase difference detection (for example, see FIG. 47). In a solid-state imaging device 1C of Comparative Example 1 illustrated in FIG. 47, one pixel includes two photodiodes (first and second photodiodes PD1 and PD2), the amount of light incident on the first and second photodiodes PD1 and PD2 changes according to the direction and distance of focus shift, and the number of electrons generated by photoelectric conversion also changes. In the solid-state imaging device 1C of Comparative Example 1, the difference in the number of electrons generated in the first and second photodiodes PD1 and PD2 is detected as a signal to measure the focus shift amount. In FIG. 47, reference numeral SW1 denotes an inter-pixel separation wall, reference numeral SW2 denotes an intra-pixel separation wall, reference numeral SS denotes a semiconductor substrate, reference numeral IF denotes an insulating film, reference numeral CF denotes a color filter, and reference numeral ML denotes a microlens.

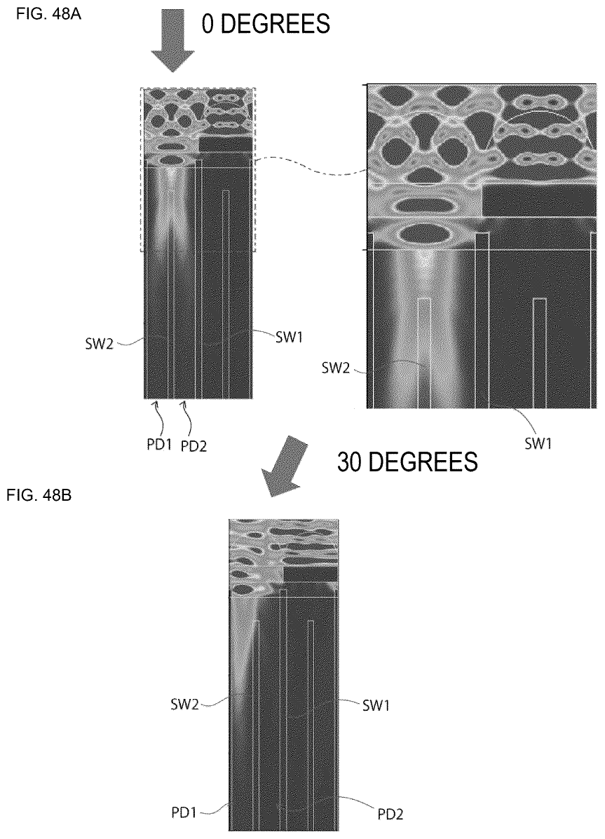

Meanwhile, in the solid-state imaging device 1C of Comparative Example 1, at the time of imaging after focus adjustment, a part of the incident light IL incident on the semiconductor substrate SS via the microlens ML, the color filter CF, and the insulating film IF is reflected by the upper portion of the intra-pixel separation wall SW2. Therefore, this causes problems such as a decrease in sensitivity and generation of flare light. FIGS. 48A and 48B are diagrams illustrating intensity distributions for each incident angle of incident light incident on the first and second photodiodes PD1 and PD2 of the solid-state imaging device 1C in FIG. 47, respectively.

Supplementarily, FIG. 48A illustrates an optical simulation result at the time of imaging (for example, at the time of incidence at an incident angle of 0° (0° incidence)). FIG. 48B illustrates an optical simulation result at the time of phase difference detection (for example, at the time of incidence at an incident angle of 30° (incidence at 30°)). As can be seen from comparison between FIGS. 48A and 48B, in the case of 0° incidence, more light is incident on the upper portion of the intra-pixel separation wall SW2 than in the case of 30° incidence, and is reflected, lost, and scattered on the upper portion.

Therefore, in view of such a problem, the inventor has developed the solid-state imaging device according to the present technology as a solid-state imaging device capable of suppressing reflection of light at the upper portion of the intra-pixel separation wall as a result of intensive studies.

In the description below, an embodiment of the present technology will be explained in detail through some examples. In the following embodiments, for convenience, the upper side in each drawing is referred to as “up”, the lower side is referred to as “down”, the left side is referred to as “left”, and the right side is referred to as “right”.

### 1. Solid-State Imaging Device According to Example 1 of an Embodiment of the Present Technology

### <<Configuration of Solid-State Imaging Device>>

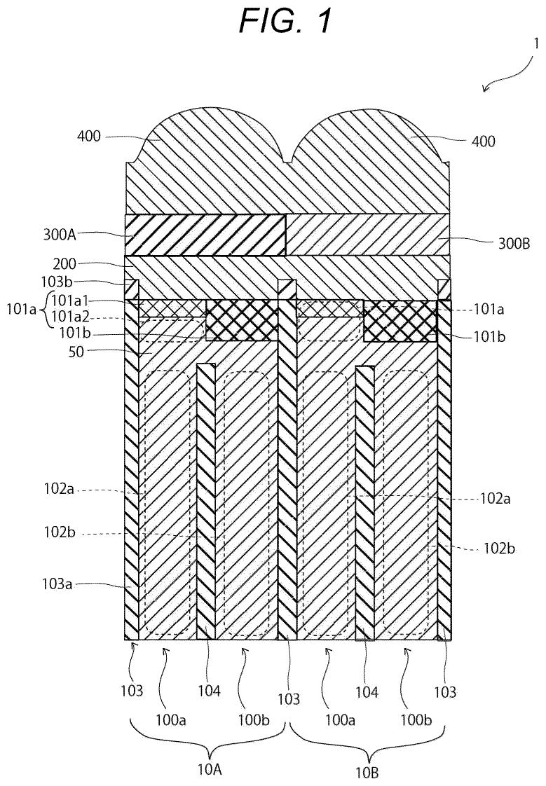

FIG. 1 is a diagram schematically illustrating a cross-sectional configuration of a solid-state imaging device 1 according to Example 1 of an embodiment of the present technology.

As an example, as illustrated in FIG. 1, the solid-state imaging device 1 includes a plurality of pixels 10 (for example, pixels 10A and 10B). The solid-state imaging device 1 is a back-illuminated solid-state imaging device (image sensor). Here, each pixel 10 is a dual pixel that serves both imaging and phase difference detection.

Each pixel 10 includes first and second light receiving units 100a and 100b adjacent to each other, and an intra-pixel separation wall 104 (separation wall) provided between the first and second light receiving units 100a and 100b. The first and second light receiving units 100a and 100b of each pixel 10 receive light of the same wavelength band (for example, any one of a red band (625 nm to 780 nm), a green band (500 to 565 nm), and a blue band (450 to 485 nm)). For example, the first and second light receiving units 100a and 100b of the pixel 10A receive light in a green band. For example, the first and second light receiving units 100a and 100b of the pixel 10B receive light in a blue band.

An inter-pixel separation wall 103 is provided between two adjacent pixels 10 (for example, the pixels 10A and 10B; hereinafter, also referred to as “adjacent pixels”). The inter-pixel separation wall 103 electrically and optically separates adjacent pixels from each other. More specifically, the inter-pixel separation wall 103 includes, as an example, a first separation portion 103a containing an insulator (for example, SiO, SiO₂, SiN, SiON, and the like) and a second separation portion 103b containing metal (for example, W, Al, Ni, and the like). As an example, the first separation portion 103a is provided over the entire region in the thickness direction (up-down direction) of the semiconductor substrate 50, and electrically isolates (insulates) adjacent pixels from each other. The second separation portion 103b is provided on an end portion (upper end portion) of the first separation portion 103a on the insulating film 200 side, and functions as a light-shielding wall that optically separates adjacent pixels. The inter-pixel separation wall 103 is formed in a lattice-like shape along the boundary lines between the adjacent pixels in a planar view, for example.

The first and second light receiving units 100a and 100b of each pixel 10, the inter-pixel separation wall 103, and the intra-pixel separation wall 104 are provided on a semiconductor substrate 50 (for example, Si substrate). As the semiconductor substrate 50, a Ge substrate, a GaAs substrate, an InGaAs substrate, or the like can be used in addition to the Si substrate.

The intra-pixel separation wall 104 of each pixel 10 electrically separates (insulates) the first and second light receiving units 100a and 100b. As an example, the intra-pixel separation wall 104 extends in the thickness direction (up-down direction) of the semiconductor substrate 50 so as to bisect a part (portion excluding the upper portion) of the semiconductor substrate 50 of each pixel 10 in the in-plane direction. That is, as an example, the intra-pixel separation wall 104 of each pixel 10 is located at the middle (center) of the two inter-pixel separation walls 103 positioned at both ends of the pixel 10. That is, the light receiving areas of the first and second light receiving units 100a and 100b are substantially the same. The intra-pixel separation wall 104 contains, for example, SiO, SiO₂, SiN, SiON, or the like.

Each pixel 10 is provided on the light incident side (light incident side, upper side, and so on) of the first and second light receiving units 100a and includes color filters 300 (for example, color filters 300A and 300B) having the wavelength band as a transmission wavelength band. For example, the pixel 10A includes a color filter 300A having a transmission wavelength band in a green band. For example, the pixel 10B includes a color filter 300B having a transmission wavelength band in a blue band.

Each pixel 10 includes a microlens 400 provided on the light incident side of the color filter 300.

Each pixel 10 includes an insulating film 200 (for example, a SiO film, a SiO₂ film, a SiN film, a SiON film, or the like) between the color filter 300 and the semiconductor substrate 50. The insulating film 200 is shared by the plurality of pixels 10.

As can be seen from the above description, the solid-state imaging device 1 has a multilayer structure in which the semiconductor substrate 50, the insulating film 200, the plurality of color filters 300, and the plurality of microlenses 400 are stacked in this order. Hereinafter, the layering direction (up-down direction) in the multilayer structure is also simply referred to as a “layering direction”.

The first light receiving unit 100a of each pixel 10 includes a first photoelectric conversion element 102a and a first phase imparting structure 101a that is provided on the light incident side of the first photoelectric conversion element 102a and imparts a first phase α to incident light (light that has been incident).

The second light receiving unit 100b of each pixel 10 includes a second photoelectric conversion element 102b and a second phase imparting structure 101b that is provided on the light incident side of the second photoelectric conversion element 102b and imparts a second phase β different from the first phase α to incident light (light that has been incident). The second phase imparting structure 101b is adjacent to the first phase imparting structure 101b.

In each pixel 10, the intra-pixel separation wall 104 described above is provided at least between the first and second photoelectric conversion elements 102a and 102b, and the first and second phase imparting structures 101a and 101b are located on the light incident side of the intra-pixel separation wall 104.

The first photoelectric conversion element 102a is provided in the semiconductor substrate 50 and photoelectrically converts incident light. Most of light via at least the first phase imparting structure 101a is incident on the first photoelectric conversion element 102a. Note that part of light via the second phase imparting structure 101b may be incident on the first photoelectric conversion element 102a.

The second photoelectric conversion element 102b is provided side by side in the in-plane direction (direction orthogonal to the layering direction) with the first photoelectric conversion element 102a via the intra-pixel separation wall 104 in the semiconductor substrate 50, and photoelectrically converts the incident light. Most of light via at least the second phase imparting structure 101b is incident on the second photoelectric conversion element 102a. Note that part of light via the first phase imparting structure 101a may be incident on the second photoelectric conversion element 102b.

The first phase imparting structure 101a includes a first portion 101al which is a portion having a refractive index different from that of the semiconductor substrate 50 and is provided on a surface of the semiconductor substrate 50 on the light incident side. The first phase imparting structure 101a further includes a second portion 101a2 that is a part of the semiconductor substrate 50 (specifically, a part of the surface layer on the light incident side of the semiconductor substrate 50) and is located on a side (lower side) opposite to the light incident side of the first portion 101al. The first portion 101al of the first phase imparting structure 101a may be formed by processing the semiconductor substrate 50, or may be a separate member (for example, a semiconductor layer or an insulating layer having a refractive index different from that of the semiconductor substrate 50) stacked on the semiconductor substrate 50.

The second phase imparting structure 101b is a structure that is provided on a surface of the semiconductor substrate 50 on the light incident side and has a refractive index different from that of the semiconductor substrate 50. The second phase imparting structure 101b may be formed by processing the semiconductor substrate 50, or may be a separate member (for example, a semiconductor layer or an insulating layer having a refractive index different from that of the semiconductor substrate 50) stacked on the semiconductor substrate 50.

Here, the surfaces of the first portion 101al and the second phase imparting structure 101b of the first phase imparting structure 101a on the light incident side are flush. As an example, the first and second phase imparting structures 101a and 101b have the same thickness (dimension in the layering direction) and the same position in the layering direction.

The first and second photoelectric conversion elements 102a and 102b are photodiodes (PD), for example. More specifically, examples of the first and second photoelectric conversion elements 102a and 102b include a PN photodiode, a PIN photodiode, a single photon avalanche photodiode (SPAD), an avalanche photo diode (APD), or the like, for example.

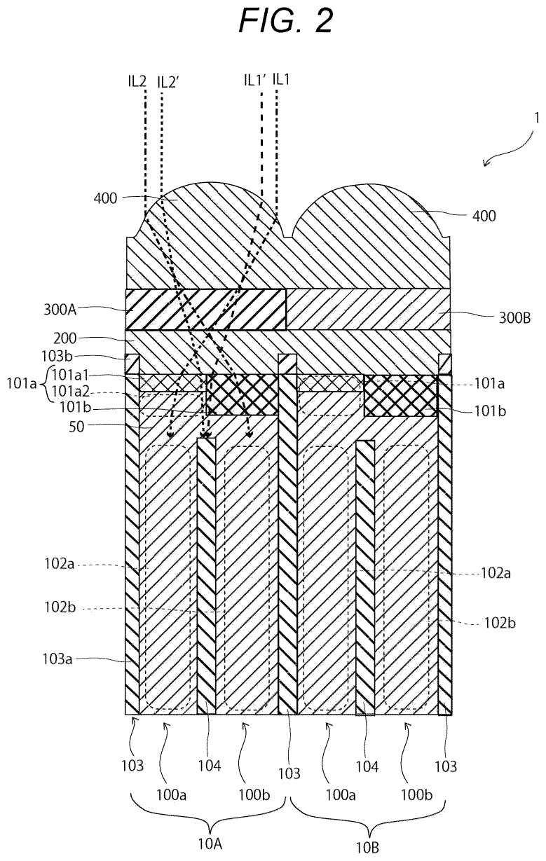

FIG. 2 is a diagram for explaining the operation of the solid-state imaging device 1. As illustrated in FIG. 2, at the time of imaging after focus adjustment, in each pixel 10, light incident (perpendicularly incident) at 0° is incident on the first and second phase imparting structures 101a and 101b via the microlens 400, the color filter 300, and the insulating film 200. At this time, the light is refracted at each interface of the pixel 10 and guided to the first and second phase imparting structures 101a and 101b.

Most of the light (for example, light IL1) incident on the first phase imparting structure 101a is imparted with the first phase α by the first phase imparting structure 101a and is refracted toward the first photoelectric conversion element 102a. Most of the light (for example, light IL2) incident on the second phase imparting structure 101b is imparted with the second phase β by the second phase imparting structure 101b and is refracted toward the second photoelectric conversion element 102b. As a result, substantially the same amount of light is incident on the first and second photoelectric conversion elements 102a and 102b, and electric signals (light-receiving signals) having substantially the same magnitude are output from the first and second photoelectric conversion elements 102a and 102b.

The remaining light (for example, light L1′) incident on the first phase imparting structure 101a is imparted with the first phase α by the first phase imparting structure 101a, and is refracted toward the intra-pixel separation wall 104. The remaining light (for example, light L2′) incident on the second phase imparting structure 101b is imparted with the second phase β by the second phase imparting structure 101b, and is refracted toward the intra-pixel separation wall 104.

At this time, the light (for example, the light L1′) to which the phase α from the first phase imparting structure 101a toward the intra-pixel separation wall 104 is imparted and the light (for example, the light L2′) to which the phase β from the second phase imparting structure 101b toward the intra-pixel separation wall 104 is imparted interfere with each other. Therefore, if the absolute value |α−β| of the phase difference between the phases α and β is within a certain range, the two lights can be partially or entirely canceled out.

Specifically, the absolute value |α−β| of the phase difference between the first and second phases α and β is preferably a value of (Nπ−π/2) or more and (Nπ+π/2) or less, more preferably a value of (Nπ−π/4) or more and (Nπ+π/4) or less, still more preferably a value of (Nπ−π/8) or more and (Nπ+π/8) or less, and still more preferably Nπ, where N is an odd number. For example, |α−β|=π (β>α) can be set. In this case, for example, α=0 and β=π can be set.

In other words, with respect to the refractive index (effective refractive index) n₁ and the thickness d₁ of the first portion 101al of the first phase imparting structure 101a, the refractive index (effective refractive index) n₂ and the thickness d₂ (≥d₁) of the second phase imparting structure 101b, the refractive index nₛ of the semiconductor substrate 50, and the wavelength λ of light, it is preferable that the following Expression (1) be satisfied, it is more preferable that the following Expression (2) be satisfied, it is still more preferable that the following Expression (3) be satisfied, and it is still more preferable that the following Expression (4) be satisfied, where N is an odd number.

$$( N λ / 2 - λ / 4 ) \leq \vert {n}_{1} {d}_{1} + {n}_{s} ( {d}_{2} - {d}_{1} ) - {n}_{2} {d}_{2} \vert \leq ( N λ / 2 + λ / 4 ) \qquad ( 1 )$$

$$( N λ / 2 - λ / 8 ) \leq \vert {n}_{1} {d}_{1} + {n}_{s} ( {d}_{2} - {d}_{1} ) - {n}_{2} {d}_{2} \vert \leq ( N λ / 2 + λ / 8 ) \qquad ( 2 )$$

$$( N λ / 2 - λ / 16 ) \leq \vert {n}_{1} {d}_{1} + {n}_{s} ( {d}_{2} - {d}_{1} ) - {n}_{2} {d}_{2} \vert \leq ( N λ / 2 + λ / 16 ) \qquad ( 3 )$$

$$\vert {n}_{1} {d}_{1} + {n}_{s} ( {d}_{2} - {d}_{1} ) - {n}_{2} {d}_{2} \vert = N λ / 2 \qquad ( 4 )$$

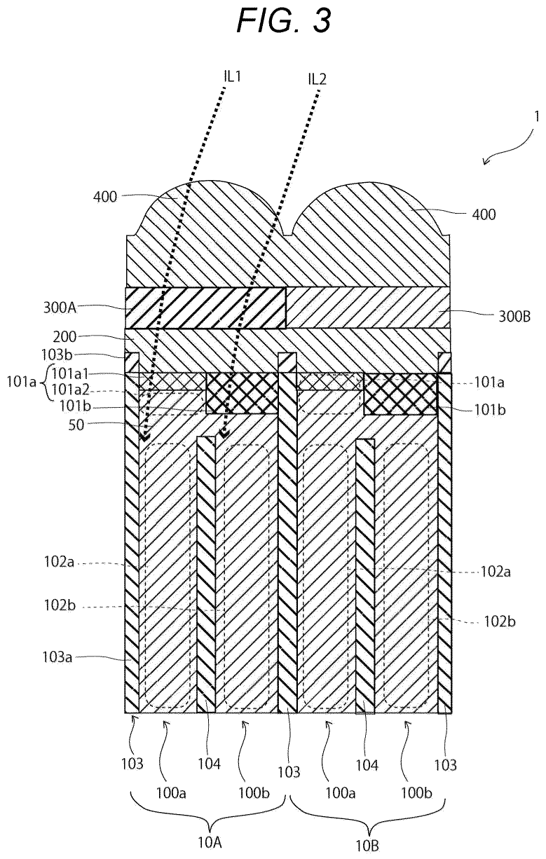

FIG. 3 is a diagram for explaining an operation (part 1) at the time of phase difference detection of the solid-state imaging device in FIG. 1. As illustrated in FIG. 3, light obliquely incident from the right side at the time of phase difference detection before focus adjustment is incident on the first and second phase imparting structures 101a and 101b via the microlens 400, the color filter 300, and the insulating film 200. At this time, more light is incident on the left first phase imparting structure 101a of the first and second phase imparting structures 101a and 101b. The light (for example, the light IL1) incident on the first phase imparting structure 101a is imparted with the first phase α by the first phase imparting structure 101a and is refracted toward the first photoelectric conversion element 102a. The light (for example, the light IL2) incident on the right second phase imparting structure 101b is imparted with the second phase β by the second phase imparting structure 101b and is refracted toward the second photoelectric conversion element 102b. As a result, more light is incident on the first photoelectric conversion element 102a, and the output of the first photoelectric conversion element 102a becomes larger than the output of the second photoelectric conversion element 102b.

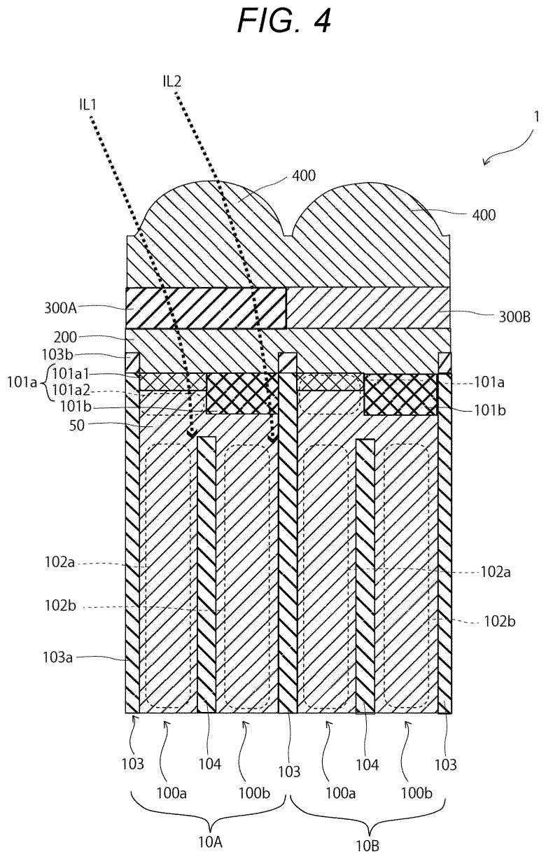

FIG. 4 is a diagram for explaining an action (part 2) at the time of phase difference detection of the solid-state imaging device in FIG. 1. As illustrated in FIG. 4, light obliquely incident from the left side at the time of phase difference detection before focus adjustment is incident on the first and second phase imparting structures 101a and 101b via the microlens 400, the color filter 300, and the insulating film 200. At this time, more light is incident on the right second phase imparting structure 101b of the first and second phase imparting structures 101a and 101b. The light (for example, the light IL2) incident on the second phase imparting structure 101b is imparted with the second phase β by the second phase imparting structure 101b and is refracted toward the second photoelectric conversion element 102b. The light (for example, the light IL1) incident on the left first phase imparting structure 101a is imparted with the first phase α by the first phase imparting structure 101a and is refracted toward the first photoelectric conversion element 102a. As a result, more light is incident on the second photoelectric conversion element 102b, and the output of the second photoelectric conversion element 102b becomes larger than the output of the first photoelectric conversion element 102a.

Note that, even at the time of phase difference detection as illustrated in FIGS. 3 and 4, reflection of light at the upper portion of the intra-pixel separation wall 104 may occur, but since not as much light as at the time of imaging is incident on the upper portion of the intra-pixel separation wall 104, there is little influence.

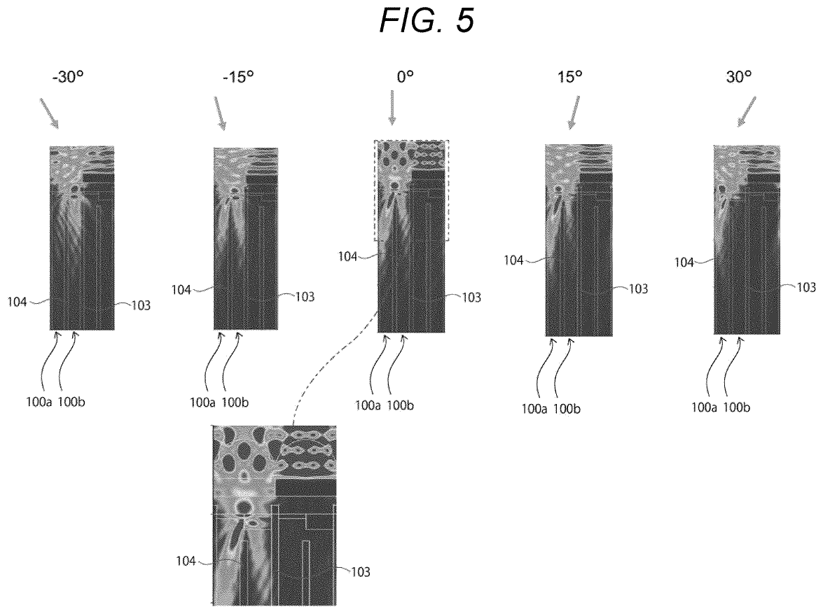

FIG. 5 is a diagram illustrating an intensity distribution for each incident angle of incident light incident on the first and second light receiving units 100a and 100b of the solid-state imaging device 1. Specifically, FIG. 5 illustrates an optical simulation result of the solid-state imaging device 1 with respect to incident light having a wavelength λ of 525 nm under the conditions of the following Table 1. In FIG. 5, the incident angle of the incident light is changed from −30° to 30° at 15° intervals. According to FIG. 5, it can be seen that the intensity of light emitted onto the intra-pixel separation wall 104 is suppressed when the incident angle is 0°, as compared with the comparative example illustrated in FIG. 48A. Therefore, reflection of light at the upper portion of the intra-pixel separation wall 104 is suppressed.

Preferred specific examples of the refractive index and the thickness at λ=525 nm of the main components of the solid-state imaging device 1 are shown in Table 1 below.

TABLE 1

| | refractive index | Thickness |
|---|---|---|
| Insulating film | 1.500 | 200 nm |
| First phase imparting | 2.570 | 51 nm |
| structure | | |
| Second phase imparting | 2.223 | 177 nm |
| structure | | |
| Semiconductor substrate | 4.166 | |

The first portion 101a1 of the first phase imparting structure 101a preferably has an antireflection function of preventing reflection of light. Therefore, improvement in sensitivity and suppression of flare light and ghost light can be expected. The antireflection condition of the first phase imparting structure 101a is that the following Expressions (5) to (7) are satisfied (here, n₁ is a refractive index of the insulating film 200).

$${d}_{1} \approx λ / 4 {n}_{1} \qquad ( 5 )$$

$${n}_{1} \approx {n}_{i} {n}_{s} / 2 \qquad ( 6 )$$

$${n}_{s} > {n}_{1} > {n}_{i} \qquad ( 7 )$$

In each of the above Expressions (5) to (7), it is preferable that the difference between the sides is as small as possible.

The second phase imparting structure 101b preferably has an antireflection function of preventing reflection of light. Improvement in sensitivity and suppression of flare light and ghost light can be expected. The antireflection condition of the second phase imparting structure 101b is that the following Expressions (8) to (10) are satisfied (here, n₁ is a refractive index of the insulating film 200).

$${d}_{2} \approx 3 λ / 4 {n}_{2} \qquad ( 8 )$$

$${n}_{2} \approx {n}_{i} {n}_{s} / 2 \qquad ( 9 )$$

$${n}_{s} > {n}_{2} > {n}_{i} \qquad ( 10 )$$

In each of the above Expressions (8) to (10), it is preferable that the difference between the sides is as small as possible.

In the semiconductor substrate 50, as an example, in addition to the first and second light receiving units 100a and 100b, the inter-pixel separation wall 103, and the intra-pixel separation wall 104, a control circuit (analog circuit; not illustrated) that controls each pixel 10 and an A/D conversion circuit (analog circuit; not illustrated) are formed.

The control circuit includes circuit elements such as transistors, for example. Specifically, as an example, the control circuit includes a plurality of pixel transistors (so-called MOS transistors) and a signal processing unit. The plurality of pixel transistors can include three transistors of a transfer transistor, a reset transistor, and an amplification transistor, for example. In addition, it can be configured by four transistors by adding a selection transistor. The signal processing unit performs phase difference detection on the basis of the electric signals from the first and second photoelectric conversion elements 102a and 102b. The A/D conversion circuit converts an analog signal generated in each pixel 10 into a digital signal.

As an example, a processing substrate (not illustrated) including, for example, a logic circuit and a memory circuit is disposed on a side (lower side) opposite to the insulating film 200 side of the semiconductor substrate 50 via a wiring layer.

The logic circuit processes a digital signal generated by the A/D conversion circuit described above. The memory circuit temporarily stores and holds the digital signal generated by the A/D conversion circuit described above and/or the digital signal processed by the logic circuit. The processing substrate has, for example, at least one layer having a multilayer structure in which a semiconductor substrate and a wiring layer are stacked.

In the processing substrate, the logic circuit and the memory circuit may be juxtaposed or stacked.

<<Operation Example of Solid-State Imaging Device>>

In the description below, an operation example of the solid-state imaging device 1 is explained. In the solid-state imaging device 1, as an example, a phase difference detection mode is executed before focus adjustment, and an imaging mode is executed after focus adjustment by the image plane phase difference AF. This cycle is repeated. Light (image light) from a subject is incident on the first and second phase imparting structures 101a and 101b via the microlens 400, the color filter 300, and the insulating film 200.

In the phase difference detection mode (for example, at the time of oblique incidence), part of the light via the first and second phase imparting structures 101a and 101b is incident on the first photoelectric conversion element 102a, and the other part of the light is incident on the second photoelectric conversion element 102b (see FIGS. 3 and 4). At this time, the first and second photoelectric conversion elements 102a and 102b perform photoelectric conversion, and individually transmit the electric signals photoelectrically converted by the first and second photoelectric conversion elements 102a and 102b to the signal processing unit. The signal processing unit detects a phase difference (focus shift) in the horizontal direction (specifically, the lateral direction) on the basis of a difference between electric signals (analog signals) from the first and second photoelectric conversion elements 102a and 102b. Image plane phase difference AF can be performed on the basis of the detection result.

In the imaging mode (for example, at the time of normal incidence), most of the light via the first phase imparting structure 101a is incident on the first photoelectric conversion element 102a, and most of the light via the second phase imparting structure 101b is incident on the second photoelectric conversion element 102b (see FIG. 2). At this time, the first and second photoelectric conversion elements 102a and 102b perform photoelectric conversion. The electric signals (analog signals) photoelectrically converted and added by the first and second photoelectric conversion elements 102a and 102b are transmitted to the A/D conversion circuit, are converted into digital signals, are temporarily stored and held in the memory circuit, and are sequentially transmitted to the logic circuit. The logic circuit processes the transmitted digital signals. Note that the digital signals can also be temporarily stored and held in the memory circuit during and/or after the processing in the logic circuit. The remaining light via the first phase imparting structure 101a and the remaining light via the second phase imparting structure 101b interfere on the way toward the intra-pixel separation wall 104 and are partially or entirely offset.

In the solid-state imaging device 1, it is preferable that the position of the microlens 400 in the pixel 10, the position of the intra-pixel separation wall 104, and the refractive indexes, thicknesses, and positions of the first and second phase imparting structures 101a and 101b are optimized so that the amount of light received by the first and second photoelectric conversion elements 102a and 102b of each pixel 10 is maximized according to the position of the pupil plane and color mixing between adjacent pixels is prevented. This also applies to a solid-state imaging device according to another embodiment.

### <<Effects of Solid-State Imaging Device>>

Hereinafter, effects of the solid-state imaging device 1 will be described. The solid-state imaging device 1 includes the pixels 10 that are adjacent to each other and include the first and second light receiving units 100a and 100b that receive light in the same wavelength band and the intra-pixel separation wall 104 provided between the first and second light receiving units 100a and 100b. The first light receiving unit 100a includes the first photoelectric conversion element 102a and the first phase imparting structure 101a that is provided on a light incident side of the first photoelectric conversion element 102a and imparts the first phase α to the incident light, and the second light receiving unit 100b includes the second photoelectric conversion element 102b and the second phase imparting structure 101b that is provided on a light incident side of the second photoelectric conversion element 102b and imparts the second phase β different from the first phase α to the incident light. In this case, the intra-pixel separation wall 104 is preferably provided at least between the first and second photoelectric conversion elements 102a and 102b, and the first and second phase imparting structures 101a and 101b are preferably located on the light incident side of the intra-pixel separation wall 104.

In the solid-state imaging device 1, the light directed to the intra-pixel separation wall 104 among the light to which the first phase α is imparted by the first phase imparting structure 101a and the light directed to the intra-pixel separation wall 104 among the light to which the second phase β is imparted by the second phase imparting structure 101b interfere and partially or entirely cancel each other.

As a result, according to the solid-state imaging device 1, it is possible to provide a solid-state imaging device capable of suppressing reflection of light at the upper portion of the intra-pixel separation wall 104.

Moreover, in the solid-state imaging device 1, the first and second phase imparting structures 101a and 101b preferably have an antireflection function. Therefore, sensitivity can be improved, and occurrence of flare light and ghost light can be suppressed.

### 2. Solid-State Imaging Device According to Example 2 of an Embodiment of the Present Technology

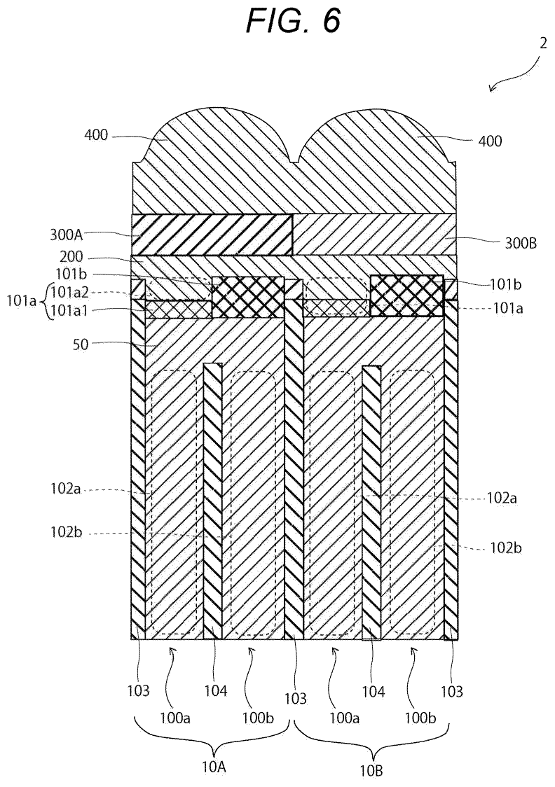

FIG. 6 is a diagram schematically illustrating a cross-sectional configuration of a solid-state imaging device 2 according to Example 2 of an embodiment of the present technology.

The solid-state imaging device 2 has a configuration substantially similar to that of the solid-state imaging device 1 according to Example 1 except that a surface (lower surface) of the first portion 101a1 of the first phase imparting structure 101a on a side opposite to the light incident side and a surface (lower surface) of the second phase imparting structure 101b on a side opposite to the light incident side are flush with each other.

In the solid-state imaging device 2, in the first phase imparting structure 101a, the second portion 101a2 is located on the light incident side (upper side) of the first portion 101a1.

Here, the first and second phase imparting structures 101a and 101b have the same thickness and the same position in the layering direction.

Also in the solid-state imaging device 2, the absolute value |α−β| of the phase difference between the first and second phases α and β is preferably a value of (Nπ−π/2) or more and (Nπ+π/2) or less, more preferably a value of (Nπ−π/4) or more and (Nπ+π/4) or less, still more preferably a value of (Nπ−π/8) or more and (Nπ+π/8) or less, and still more preferably Nπ, where N is an odd number. For example, |α−β|=π (β>α) can be set. In this case, for example, α=0 and β=π can be set.

In other words, with respect to the refractive index n₁ and the thickness d₁ of the first portion 101a1 of the first phase imparting structure 101a, the refractive index n₂ and the thickness d₂ (≥d1) of the second phase imparting structure 101b, the refractive index n₁ of the insulating film 200, and the wavelength λ of light, it is preferable that the following Expression (11) be satisfied, it is more preferable that the following Expression (12) be satisfied, it is still more preferable that the following Expression (13) be satisfied, and it is still more preferable that the following Expression (14) be satisfied, where N is an odd number.

$$( N λ / 2 - λ / 4 ) \leq \vert {n}_{1} {d}_{1} + {n}_{i} ( {d}_{2} - {d}_{1} ) - {n}_{2} {d}_{2} \vert \leq ( N λ / 2 + λ / 4 ) \qquad ( 11 )$$

$$( N λ / 2 - λ / 8 ) \leq \vert {n}_{1} {d}_{1} + {n}_{i} ( {d}_{2} - {d}_{1} ) - {n}_{2} {d}_{2} \vert \leq N λ / 2 + λ / 8 ) \qquad ( 12 )$$

$$( N λ / 2 - λ / 16 ) \leq \vert {n}_{1} {d}_{1} + {n}_{i} ( {d}_{2} - {d}_{1} ) - {n}_{2} {d}_{2} \vert \leq N λ / 2 + λ / 16 ) \qquad ( 13 )$$

$$\vert {n}_{1} \times {d}_{1} + {n}_{i} ( {d}_{2} - {d}_{1} ) - {n}_{2} {d}_{2} \vert = N λ / 2 \qquad ( 14 )$$

Also in the solid-state imaging device 2, the first portion 101a1 of the first phase imparting structure 101a preferably has an antireflection function of preventing reflection of light. That is, the above Expressions (5) to (7) are preferably satisfied.

Also in the solid-state imaging device 2, the second phase imparting structure 101b preferably has an antireflection function of preventing reflection of light. That is, the above Expressions (8) to (10) are preferably satisfied.

According to the solid-state imaging device 2, effects similar to those of the solid-state imaging device 1 according to Example 1 are obtained.

### 3. Solid-State Imaging Device According to Example 3 of an Embodiment of the Present Technology

FIG. 4 is a diagram schematically illustrating a cross-sectional configuration of a solid-state imaging device 3 according to Example 3 of an embodiment of the present technology.

The solid-state imaging device 3 has a configuration substantially similar to that of the solid-state imaging device 1 according to Example 1 except that the first portion 101a1 of the first phase imparting structure 101a and the second phase imparting structure 101b are not flush with both the surface (upper surface) on the light incident side and the surface (lower surface) on a side opposite to the light incident side.

Here, the first phase imparting structure 101a includes a first portion 101a1 which is a portion having a refractive index different from that of the semiconductor substrate 50 and is provided on a surface (upper surface) of the semiconductor substrate 50 on the light incident side, a second portion 101a2 which is a part of the insulating film 200 and is located on the light incident side (upper side) of the first portion 101a1, and a third portion 101a3 which is a part of the semiconductor substrate 50 and is located on a side (lower side) opposite to the light incident side of the first portion 101a1. Here, the thicknesses and the positions in the layering direction of the first and second phase imparting structures 101a and 101b are the same.

Also in the solid-state imaging device 3, the absolute value |α−β| of the phase difference between the first and second phases α and β is preferably a value of (Nπ−π/2) or more and (Nπ+π/2) or less, more preferably a value of (Nπ−π/4) or more and (Nπ+π/4) or less, still more preferably a value of (Nπ−π/8) or more and (Nπ+π/8) or less, and still more preferably Nπ, where N is an odd number. For example, |α−β|=π (β>α) can be set. In this case, for example, α=0 and β=π can be set.

In other words, with respect to the refractive index n₁ and the thickness d₁ of the first portion 101a1 of the first phase imparting structure 101a, the refractive index n₂ and the thickness d₂ (≥d1) of the second phase imparting structure 101b, the refractive index n₁ of the insulating film 200, the thickness d₁ of the second portion 101a2 of the first phase imparting structure 101a, the refractive index nₛ of the semiconductor substrate 50, the thickness dₛ of the third portion 101a3 of the first phase imparting structure 101a, and the wavelength λ of light, it is preferable to satisfy the following Expression (15), it is more preferable to satisfy the following Expression (16), it is still more preferable to satisfy the following Expression (17), and it is still more preferable to satisfy the following Expression (18), where N is an odd number.

$$( N λ / 2 - λ / 4 ) \leq \vert {n}_{1} {d}_{1} + {n}_{s} {d}_{s} + {n}_{i} {d}_{i} - {n}_{2} {d}_{2} \vert \leq N λ / 2 + λ / 4 ) ( where {d}_{1} + {d}_{s} + {d}_{i} = {d}_{2} ) \qquad ( 15 )$$

$$( N λ / 2 - λ / 8 ) \leq \vert {n}_{1} {d}_{1} + {n}_{s} {d}_{s} + {n}_{i} {d}_{i} - {n}_{2} {d}_{2} \vert \leq N λ / 2 + λ / 8 ) ( where {d}_{1} + {d}_{s} + {d}_{i} = {d}_{2} ) \qquad ( 16 )$$

$$( N λ / 2 - λ / 16 ) \leq \vert {n}_{1} {d}_{1} + {n}_{s} {d}_{s} + {n}_{i} {d}_{i} - {n}_{2} {d}_{2} \vert \leq N λ / 2 + λ / 16 ) ( where {d}_{1} + {d}_{s} + {d}_{i} = {d}_{2} ) \qquad ( 17 )$$

$$\vert {n}_{1} {d}_{1} + {n}_{s} {d}_{s} + {n}_{i} {d}_{i} - {n}_{2} {d}_{2} \vert = N λ / 2 ( where {d}_{1} + {d}_{s} + {d}_{i} = {d}_{2} ) \qquad ( 18 )$$

Also in the solid-state imaging device 3, the first portion 101a1 of the first phase imparting structure 101a preferably has an antireflection function of preventing reflection of light. That is, the above Expressions (5) to (7) are preferably satisfied.

Also in the solid-state imaging device 3, the second phase imparting structure 101b preferably has an antireflection function of preventing reflection of light. That is, the above Expressions (8) to (10) are preferably satisfied.

According to the solid-state imaging device 3, effects similar to those of the solid-state imaging device 1 according to Example 1 are obtained.

### 4. Solid-State Imaging Device According to Example 4 of an Embodiment of the Present Technology

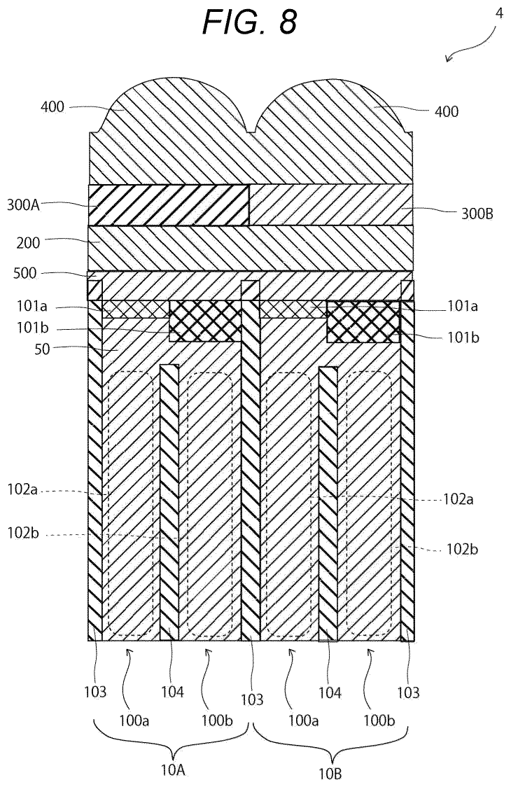

FIG. 8 is a diagram schematically illustrating a cross-sectional configuration of a solid-state imaging device 4 according to Example 4 of an embodiment of the present technology.

As illustrated in FIG. 8, the solid-state imaging device 4 has a configuration substantially similar to that of the solid-state imaging device 1 according to Example 1 except that each pixel 10 is arranged on the light incident side of the first and second phase imparting structures 101a and 101b and has an antireflection structure 500 that prevents reflection of light.

As an example, the antireflection structure 500 is provided between the first and second phase imparting structures 101a and 101b and the insulating film 200. The antireflection structure 500 may be any structure as long as it has a function of preventing reflection of light, such as an antireflection film (AR coating: a multilayer film in which different insulating layers are stacked) and a reflectance adjustment layer (see WO 2016/194654).

According to the solid-state imaging device 4, effects similar to those of the solid-state imaging device 1 according to Example 1 are obtained, and reflected light from the surface (upper surface) on the light incident side of the semiconductor substrate 50 and the first and second phase imparting structures 101a and 101b can be further reduced.

### 5. Solid-State Imaging Device According to Example 5 of an Embodiment of the Present Technology

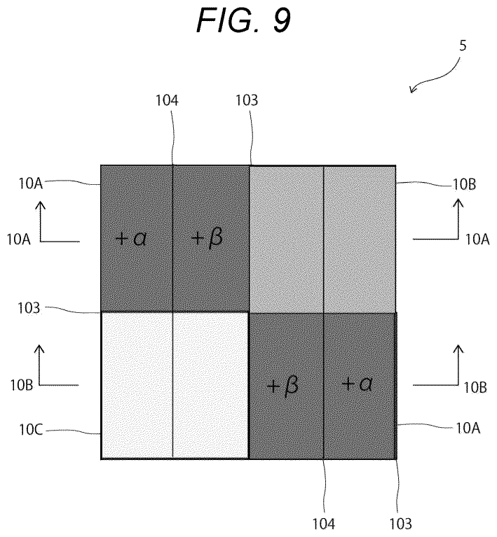

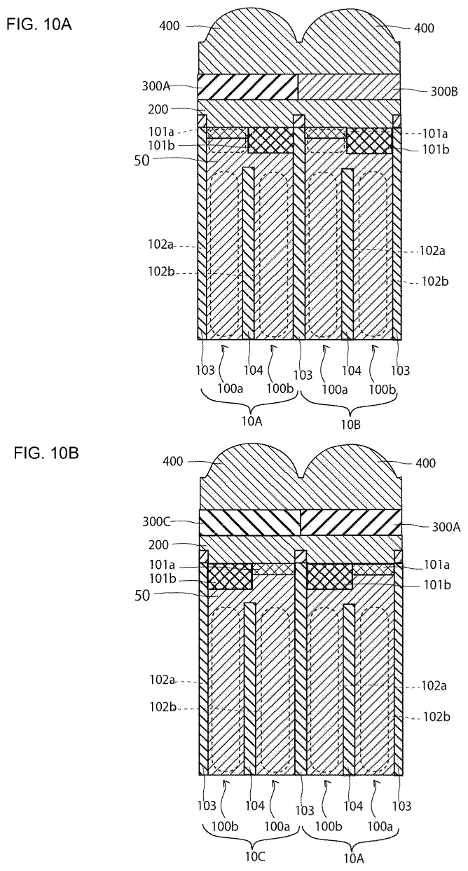

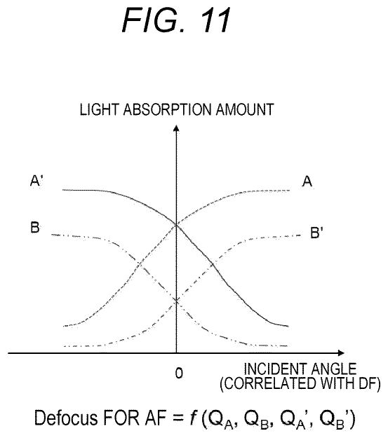

FIG. 9 is a diagram schematically illustrating a planar configuration of a solid-state imaging device 5 according to Example 5 of an embodiment of the present technology. FIG. 10A is a diagram schematically illustrating a cross section taken along line 10A-10A in FIG. 9. FIG. 10B is a diagram schematically illustrating a cross section taken along line 10B-10B in FIG. 9. FIG. 11 is a graph illustrating a relationship between an incident angle of light on the first and second phase imparting structures and a light absorption amount.

In the solid-state imaging device 5, as illustrated in FIGS. 9, 10A, and 10B, a plurality of pixels 10 is arranged in a Bayer array. Hereinafter, the pixel 10A corresponding to the green band is also referred to as a “green pixel 10A”, the pixel 10C corresponding to the red band is also referred to as a “red pixel 10C”, and the pixel 10B corresponding to the blue band is also referred to as a “blue pixel 10B”.

Here, as illustrated in FIG. 5, the intensity distribution of the incident light in the first and second light receiving units 100a and 100b is asymmetric between the left and right corresponding incident angles (e.g. −30° and 30°, −15° and 15°). Therefore, in order to reduce the influence of the asymmetry, in the solid-state imaging device 5, as illustrated in FIGS. 9, 10A, and 10B, between the pair of adjacent green pixels 10A, the positional relationship in the in-plane direction (left-right direction) between the first phase imparting structure 101a that imparts the first phase α to the incident light and the second phase imparting structure 101b that imparts the second phase β to the incident light, that is, the positional relationship in the in-plane direction (left-right direction) between the first and second light receiving units 100a and 100b is reversed.

Here, the first light receiving unit 100a is located on the left side and the second light receiving unit 100b is located on the right side in the green pixel 10A in the upper left of FIG. 9, and the first light receiving unit 100a is located on the right side and the second light receiving unit 100b is located on the left side in the green pixel 10A in the lower right of FIG. 9. Alternatively, the first light receiving unit 100a may be located on the right side and the second light receiving unit 100b may be located on the left side in the green pixel 10A in the upper left of FIG. 9, and the first light receiving unit 100a may be located on the left side and the second light receiving unit 100b may be located on the right side in the green pixel 10A in the lower right of FIG. 9.

Similarly, the positional relationship in the in-plane direction (left and right) between the first and second phase imparting structures 101a and 101b may be reversed between the pair of red pixels 10C, or the positional relationship in the in-plane direction (left and right) between the first and second phase imparting structures 101a and 101b may be reversed between the pair of blue pixels 10B.

When the first light receiving unit 100a of the green pixel 10A in the upper left of FIG. 9 is A, the second light receiving unit 100b is B, the first light receiving unit 100a of the green pixel 10A in the lower right of FIG. 9 is A′, and the second light receiving unit 100b is B′, the relationship between the number of electrons Q_{A}, Q_{B}, Q_{A}′, and Q_{B}′ generated by photoelectric conversion in A, B, A′, and B′ and the incident angle is as illustrated in FIG. 11. Since the defocus amount in the autofocus is a function of the number of electrons Q_{A}, Q_{B}, Q_{A}′, and Q_{B}′ generated in the four light receiving units, the defocus amount can be accurately detected by detecting signals of the number of electrons Q_{A}, Q_{B}, Q_{A}′, and Q_{B}′

Therefore, as the influence of the asymmetry of the intensity distribution of the incident light in the first and second light receiving units 100a and 100b between the left and right corresponding incident angles (e.g. −30° and 30°, −15° and 15°) is reduced, the phase difference detection can be performed with higher accuracy, and the defocus amount can be detected more accurately.

According to the solid-state imaging device 5, it is possible to achieve a solid-state imaging device having pixels arranged in a Bayer array capable of achieving effects similar to those of the solid-state imaging device 1 according to Example 1 and performing phase difference detection with high accuracy.

### 6. Solid-State Imaging Device According to Example 6 of an Embodiment of the Present Technology

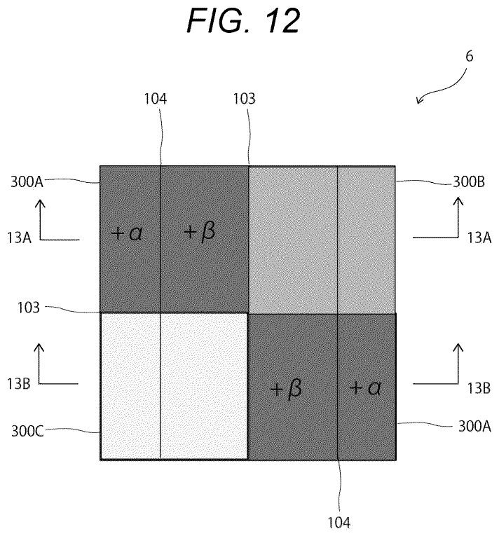

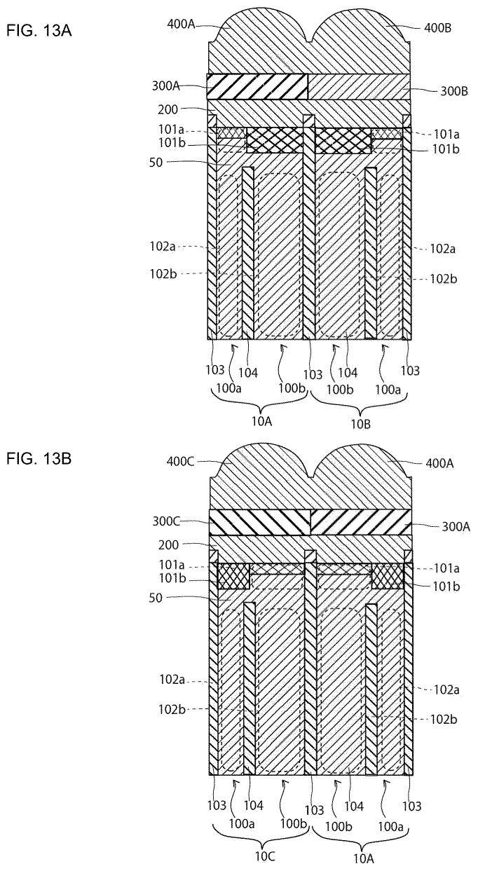

FIG. 12 is a diagram schematically illustrating a planar configuration of a solid-state imaging device 6 according to Example 6 of an embodiment of the present technology. FIG. 13A is a diagram schematically illustrating a cross section taken along line 13A-13A in FIG. 12. FIG. 13B is a diagram schematically illustrating a cross section taken along line 13B-13B in FIG. 12.

The solid-state imaging device 6 has a configuration substantially similar to that of the solid-state imaging device 5 according to Example 5 except that the light receiving areas of the first and second light receiving units 100a and 100b are different.

In the solid-state imaging device 6, in each pixel 10, the light receiving area of the second light receiving unit 100b having the second phase imparting structure 101b that imparts the second phase β (>α) to the incident light is larger than the light receiving area of the first light receiving unit 100a having the first phase imparting structure 101a that imparts the first phase α to the incident light. That is, in each pixel 10, the light receiving area of the second phase imparting structure 101b is larger than the light receiving area of the first phase imparting structure 101a, and the light receiving area of the second photoelectric conversion element 102b is larger than the light receiving area of the first photoelectric conversion element 102a.

Here, in the green pixel 10A in the upper left of FIG. 12, the first light receiving unit 100a is located on the left side and the second light receiving unit 100b is located on the right side, and the position of the intra-pixel separation wall 104 in the left-right direction is shifted from the center to the left side. In the green pixel 10A in the lower right of FIG. 12, the first light receiving unit 100a is located on the right side and the second light receiving unit 100b is located on the left side, and the position of the intra-pixel separation wall 104 in the left-right direction is shifted from the center to the right. Here, the shift amount (offset amount) of the intra-pixel separation wall 104 is the same between the adjacent green pixels 10A, but may be different.

Note that, in the green pixel 10A in the upper left of FIG. 12, the first light receiving unit 100a may be located on the right side and the second light receiving unit 100b may be located on the left side, and the position of the intra-pixel separation wall 104 in the left-right direction may be shifted from the center to the right side. In the green pixel 10A in the lower right of FIG. 12, the first light receiving unit 100a may be located on the left side and the second light receiving unit 100b may be located on the right side, and the position of the intra-pixel separation wall 104 in the left-right direction may be shifted from the center to the left side.

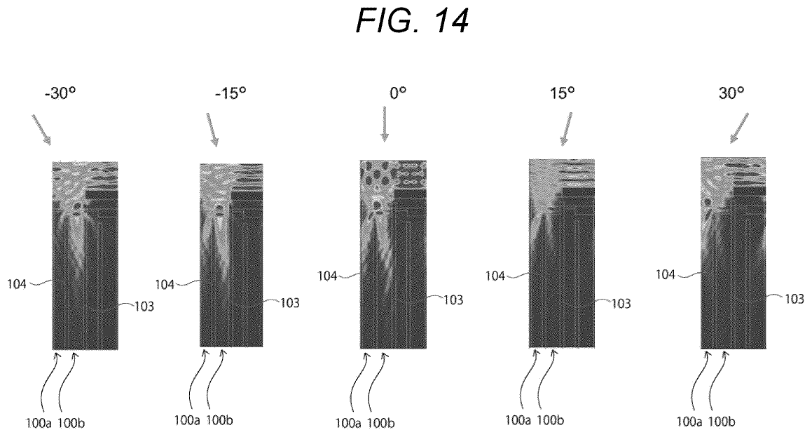

FIG. 14 is a diagram illustrating an intensity distribution for each incident angle of incident light incident on the first and second light receiving units of the solid-state imaging device 6. Specifically, FIG. 14 illustrates optical simulation results of the solid-state imaging device 6 for light having a wavelength of 525 nm under the conditions of Table 1 above. In FIG. 14, the incident angle of the incident light is changed from −30° to 30° at 150 intervals. According to FIG. 14, it can be seen that the intensity of the light emitted onto the intra-pixel separation wall 104 is suppressed when the incident angle is 0°, and the asymmetry of the light intensity distribution in the first and second light receiving units 100a and 100b between the left and right corresponding incident angles is reduced (the symmetry is improved).

According to the solid-state imaging device 6, it is possible to provide a solid-state imaging device having pixels arranged in a Bayer array capable of achieving effects similar to those of the solid-state imaging device 1 according to Example 1 and performing phase difference detection with higher accuracy.

### 7. Solid-State Imaging Device According to Example 7 of an Embodiment of the Present Technology

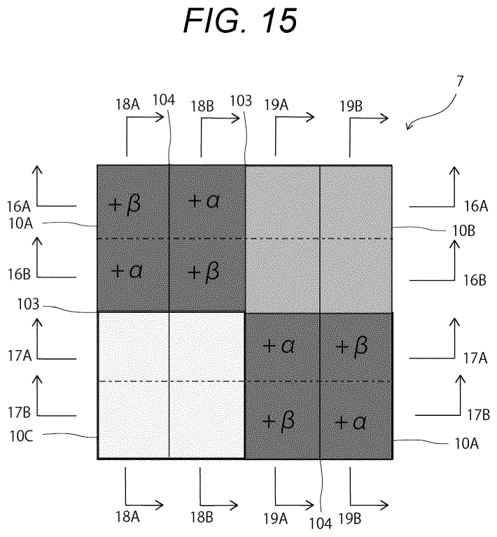

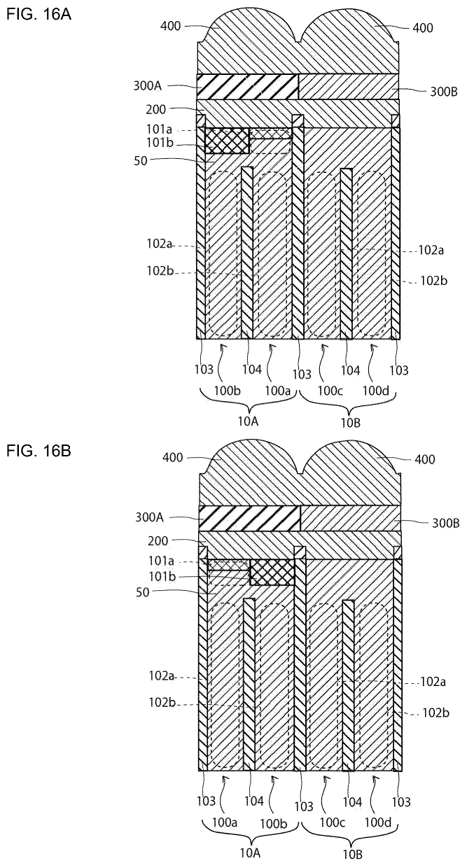

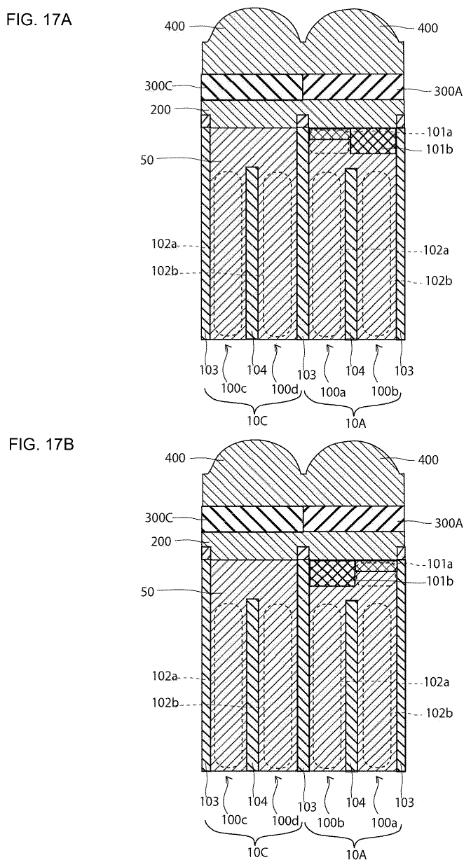

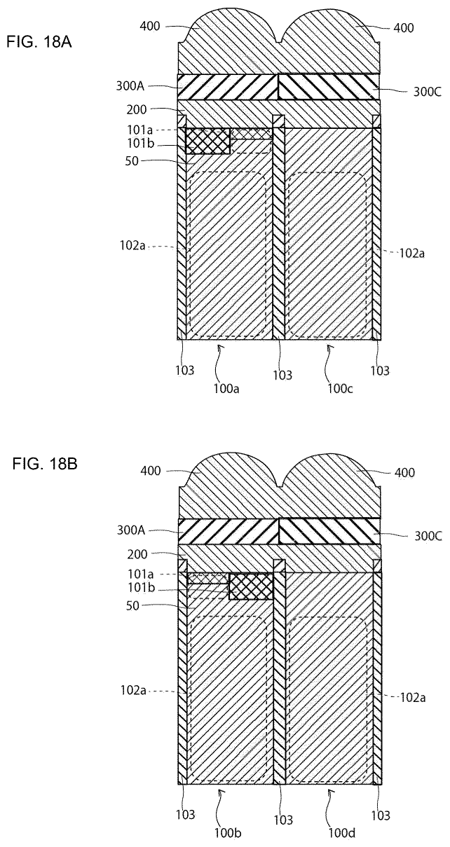

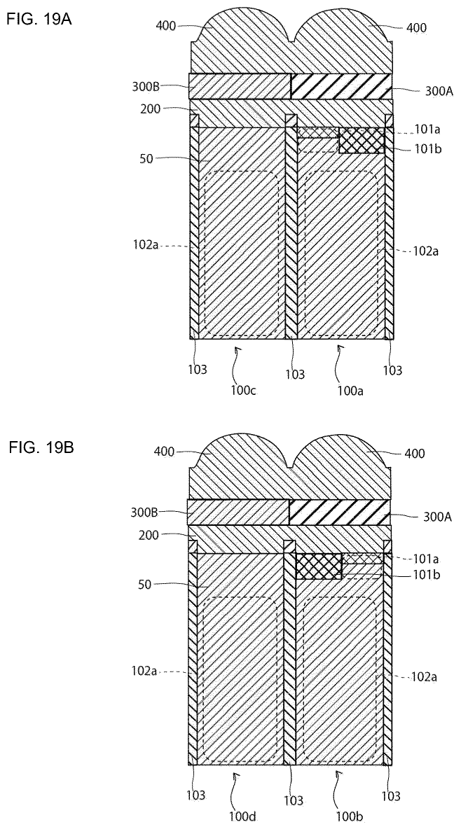

FIG. 15 is a diagram schematically illustrating a planar configuration of a solid-state imaging device 7 according to Example 7 of an embodiment of the present technology. FIG. 16A is a diagram schematically illustrating a cross section taken along line 16A-16A in FIG. 15. FIG. 16B is a diagram schematically illustrating a cross section taken along line 16B-16B in FIG. 15. FIG. 17A is a diagram schematically illustrating a cross section taken along line 17A-17A in FIG. 15. FIG. 17B is a diagram schematically illustrating a cross section taken along line 17B-17B in FIG. 15. FIG. 18A is a diagram schematically illustrating a cross section taken along line 18A-18A in FIG. 15. FIG. 18B is a diagram schematically illustrating a cross section taken along line 18B-18B in FIG. 15. FIG. 19A is a diagram schematically illustrating a cross section taken along line 19A-19A in FIG. 15. FIG. 19B is a diagram schematically illustrating a cross section taken along line 19B-19B in FIG. 15.

In the solid-state imaging device 7, as illustrated in FIGS. 15 to 19B, the first light receiving unit 100a of the pixel 10A further includes a second phase imparting structure 101b adjacent to the first phase imparting structure 101a. Light via the second phase imparting structure 101b of the first light receiving unit 100a is also incident on the first photoelectric conversion element 102a of the pixel 10A. The second light receiving unit 100b of the pixel 10A further includes a first phase imparting structure 101a adjacent to the second phase imparting structure 101b. Light via the first phase imparting structure of the second light receiving unit 100b is also incident on the second photoelectric conversion element 102b of the pixel 10A. In the pixel 10A, the first and second phase imparting structures 101a and 101b are alternately arranged in the first and second directions (for example, the 16A-16A line direction and the 18A-18A line direction in FIG. 15) orthogonal to each other in the plane.

In the solid-state imaging device 7, each pixel 10A is divided into four regions, and the first and second phase imparting structures 101a and 101b are alternately arranged. Here, none of the two light receiving units 100c and 100d of the pixel 10B and the two light receiving units 100c and 100d of the pixel 10C has the first and second phase imparting structures 101a and 101b, but the two light receiving units 100c and 100d of the pixel 10B and/or the pixel 10C may have the first and second phase imparting structures 101a and 101b.

The inter-pixel separation wall 104 extends in the longitudinal direction in FIG. 15, but does not extend in the lateral direction. That is, each pixel 10A is insulated in the lateral direction but not in the longitudinal direction. Therefore, the symmetry of the distribution of the number of generated electrons between the right and left corresponding incident angles is improved, and the defocus amount can be detected with high accuracy in one pixel 10A.

According to the solid-state imaging device 7, it is possible to provide a solid-state imaging device having pixels arranged in a Bayer array capable of achieving effects similar to those of the solid-state imaging device 1 according to Example 1 and performing phase difference detection with higher accuracy.

### 8. Solid-State Imaging Device According to Example 8 of an Embodiment of the Present Technology

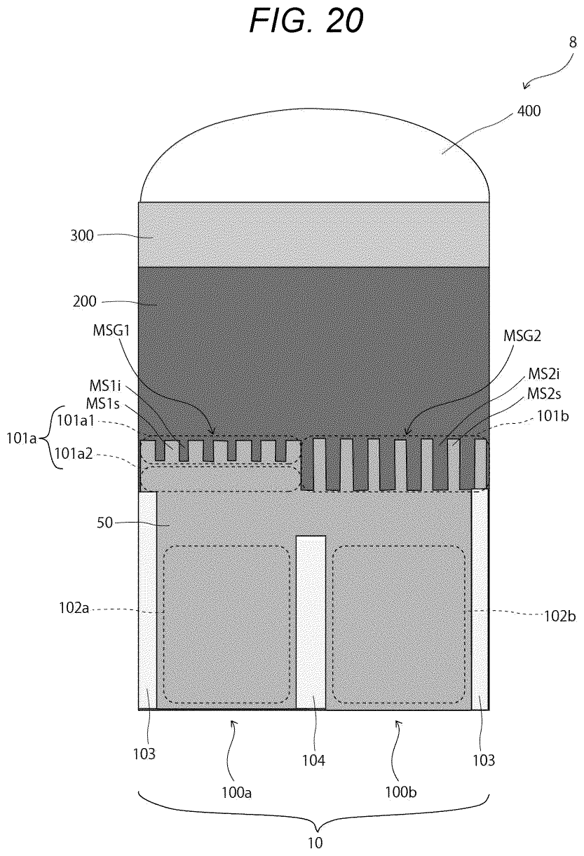

FIG. 20 is a diagram schematically illustrating a cross-sectional configuration of a solid-state imaging device 8 according to Example 8 of an embodiment of the present technology.

In the solid-state imaging device 8, as illustrated in FIG. 20, the first portion 101a1 of the first phase imparting structure 101a has a first microstructure group MSG1 including a plurality of first microstructures MS1 (for example, MS1s and MS1i), and the second phase imparting structure 101b has a second microstructure group MSG2 including a plurality of second microstructures MS2 (for example, MS2s and MS2i). Each of the first and second microstructure groups MSG1 and MSG2 has a reflectance adjustment function (see, for example, WO 2016/194654 A) in addition to the phase imparting function.

The plurality of first microstructures MS1 includes a plurality of first microstructures MS1s (concave portions or convex portions) formed on a surface of the semiconductor substrate 50 on the light incident side, and a first microstructure MS1i (convex portions or concave portions) formed on a surface of the insulating film 200 on a side opposite to the light incident side. The first microstructures MS1s and MS1i are alternately arranged without a gap in the in-plane direction. The first microstructure group is set to have a desired effective refractive index by adjusting a first ratio that is a ratio of a sum of volumes (total volume) of the first microstructure MS1s and a sum of volumes (total volume) of the first microstructure MS1i. Specifically, the setting is performed by adjusting the diameter, width, depth, height, pitch, and interval of the first microstructures MS1s and MS1i according to the color of the pixel 10. These are adjusted to, for example, about several tens to several hundreds nm.

The plurality of second microstructures MS2 includes a plurality of second microstructures MS2s (concave portions or convex portions) formed on a surface of the semiconductor substrate 50 on the light incident side, and a first microstructure MS2i (convex portions or concave portions) formed on a surface of the insulating film 200 on a side opposite to the light incident side. The second microstructures MS2s and MS2i are alternately arranged in the in-plane direction without any gap. The second microstructure group is set to have a desired effective refractive index by adjusting a second ratio that is a ratio of a sum of volumes (total volume) of the second microstructure MS2s and a sum of volumes (total volume) of the second microstructure MS2i. Specifically, the setting is performed by adjusting the diameters and heights (or depths) of the second microstructures MS2s and MS2i. These are adjusted to, for example, about several tens to several hundreds nm.

The first and second ratios are set to different values. Therefore, the effective refractive indexes of the first and second microstructure groups MSG1 and MSG2 are different.

In the solid-state imaging device 8 described above, the plurality of first microstructures MS1 includes the first and second types of first microstructures MS1s and MS1i having different refractive indexes (effective refractive indexes) and alternately arranged in the in-plane direction, and the plurality of second microstructures MS2 includes the first and second types of second microstructures MS2s and MS2i having different refractive indexes (effective refractive indexes) and alternately arranged in the in-plane direction. In this case, the ratio of the sum of the volumes of the first microstructures MS1s of the first type and the sum of the volumes of the first microstructures MS1i of the second type is different from the ratio of the sum of the volumes of the second microstructures MS2s of the first type and the sum of the volumes of the second microstructures MS2i of the second type.

### <<Method for Manufacturing Solid-State Imaging Device>>

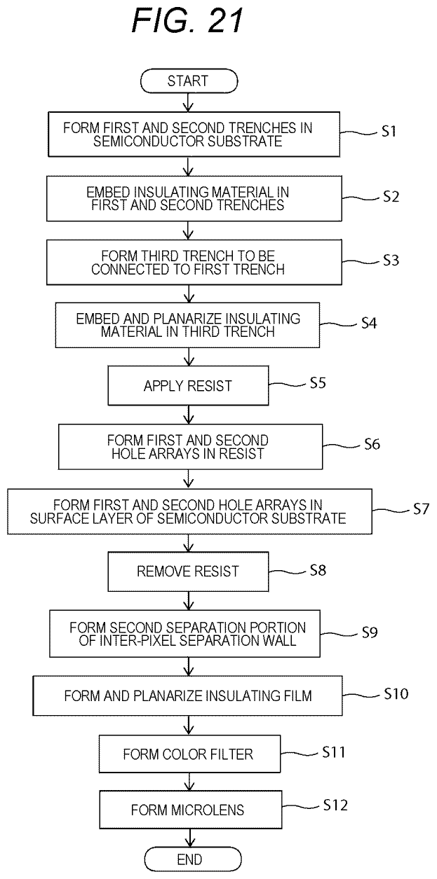

In the description below, a method for manufacturing the solid-state imaging device 8 is explained with reference to a flowchart in FIG. 21 and others. Note that, separately from the flow of FIG. 21, for example, a step of forming the first and second photoelectric conversion elements 102a and 102b on the semiconductor substrate 50, a step of stacking a wiring layer on the semiconductor substrate 50, a step of forming a logic circuit and a memory circuit on the semiconductor substrate of the processing substrate, a step of stacking a wiring layer on the semiconductor substrate of the processing substrate, a step of bonding the wiring layer of the semiconductor substrate 50 and the wiring layer of the processing substrate facing each other, and the like are performed.

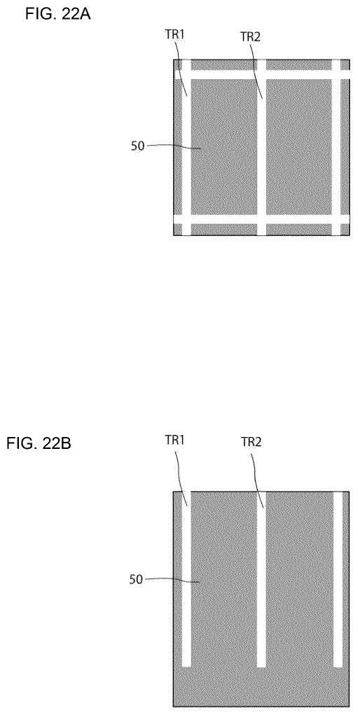

In the first step S1, first and second trenches TR1 and TR2 are formed in the semiconductor substrate 50. Specifically, the first trench TR1 for forming a part 103a1 of the first separation portion 103a of the inter-pixel separation wall 103 and the second trench TR2 for forming the intra-pixel separation wall 104 are formed in the semiconductor substrate 50 by photolithography and etching (see the plan view of FIG. 22A and the cross-sectional view of FIG. 22B).

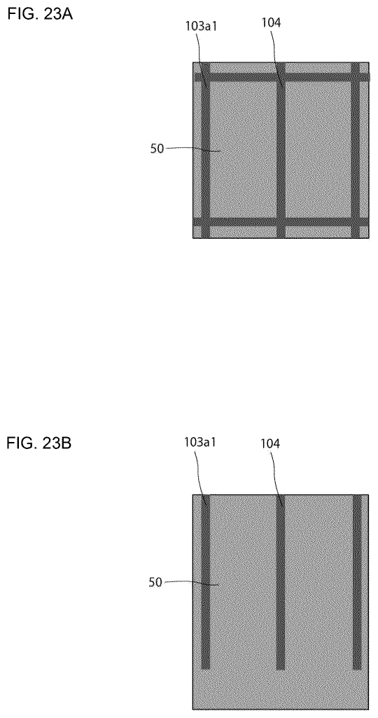

In the next step S2, an insulating material (for example, SiO) is embedded in the first and second trenches TR1 and TR2 to form the part 103a1 of the first separation portion 103a and the intra-pixel separation wall 104 (see the plan view of FIG. 23A and the cross-sectional view of FIG. 23B).

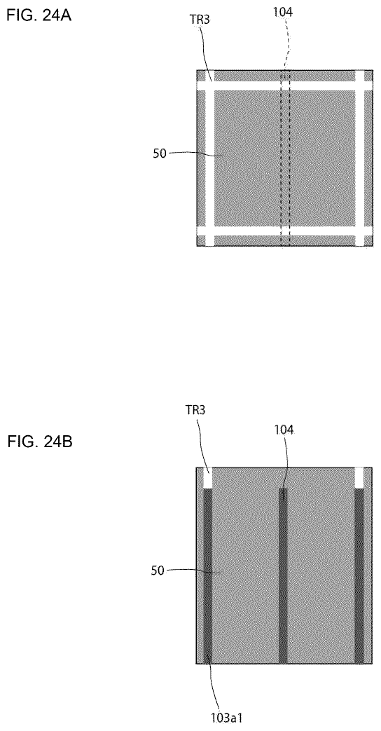

In the next step S3, the semiconductor substrate 50 is inverted, the upper surface is polished, and then a third trench TR3 connected to the first trench TR1 is formed by photolithography and etching (see the plan view of FIG. 24A and the cross-sectional view of FIG. 24B).

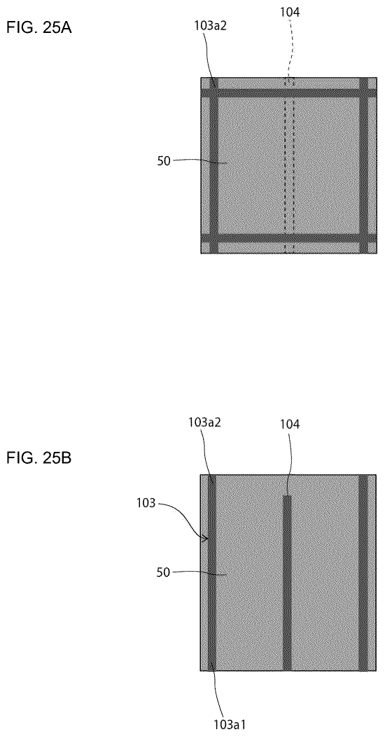

In the next step S4, an insulating material (for example, SiO) is embedded in the third trench TR3 and planarized to form the other portion 103a2 of the first separation portion 103a of the inter-pixel separation wall 103 (see the plan view of FIG. 25A and the cross-sectional view of FIG. 25B). As a result, the first separation portion 103a is completed.

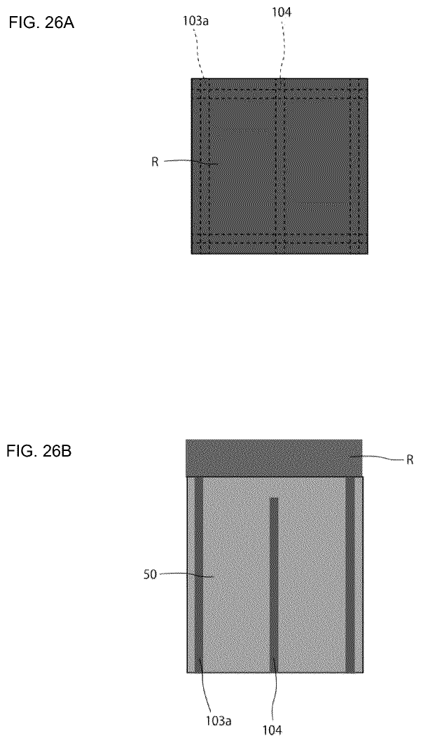

In the next step S5, a resist R is applied to the entire surface (see the plan view of FIG. 26A and the cross-sectional view of FIG. 26B).

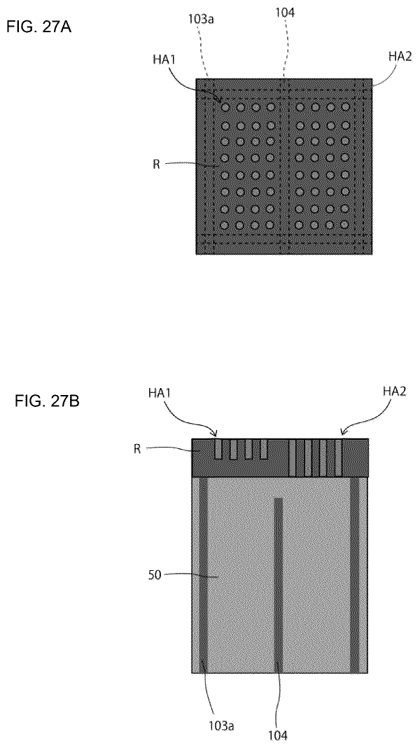

In the next step S6, first and second hole arrays HA1 and HA2 are formed in the resist R (see the plan view of FIG. 27A and the cross-sectional view of FIG. 27B). Specifically, the first hole array HA1 for forming the first microstructure group MSG1 and the second hole array HA2 for forming the second microstructure group MSG2 are formed in the resist R by nanoimprint lithography. Each hole array includes a plurality of microholes arranged in an array. At this time, the hole pitch, the hole diameter, and the hole depth of each of the first and second hole arrays HA1 and HA2 are optimized on the basis of the color (wavelength) of the pixel 10.

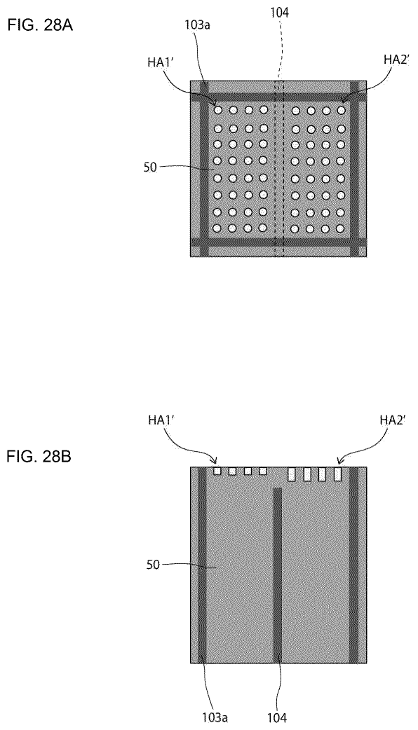

In the next step S7, first and second hole arrays HA1′ and HA2′ are formed on the surface layer of the semiconductor substrate 50 by etching back the resist R using a mask (see the plan view of FIG. 28A and the cross-sectional view of FIG. 28B).

In the next step S8, the resist R is removed.

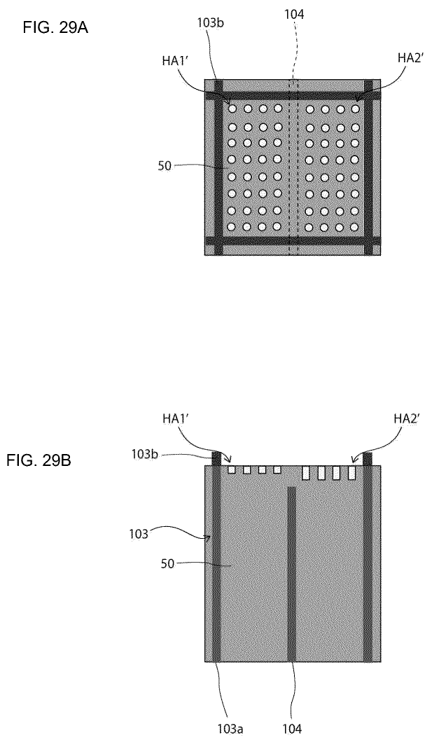

In the next step S9, the second separation portion 103b of the inter-pixel separation wall 103 is formed (see the plan view of FIG. 29A and the cross-sectional view of FIG. 29B). Specifically, the second separation portion 103b (for example, W) is formed on the surface (upper surface) of the semiconductor substrate 50 so as to be connected to the first separation portion 103a by photolithography and etching. As a result, the inter-pixel separation wall 103 is completed.

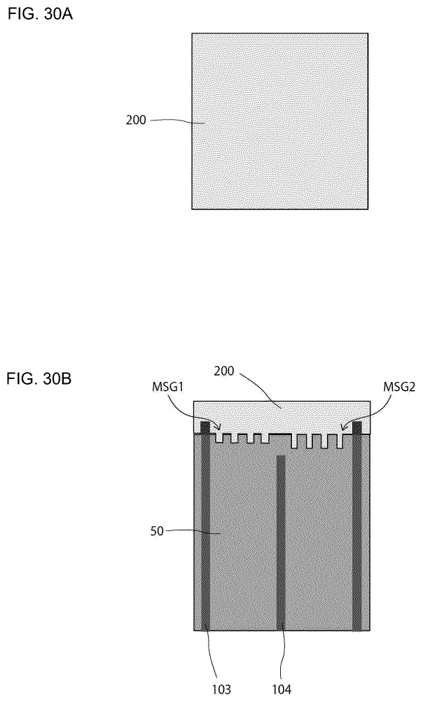

In the next step S10, the insulating film 200 is formed and planarized (see the plan view of FIG. 30A and the cross-sectional view of FIG. 30B). Specifically, the insulating film 200 is formed on the entire surface of the semiconductor substrate 50 to embed the first and second hole arrays HA1′ and HA2′. As a result, the first and second microstructure groups MSG1 and MSG2 are formed. Thereafter, the insulating film 200 is planarized.

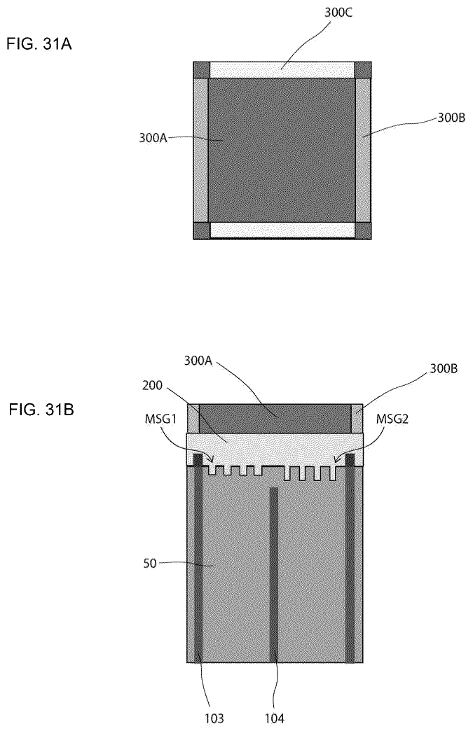

In the next step S11, the color filter 300 is formed (see the plan view of FIG. 31A and the cross-sectional view of FIG. 31B). Specifically, a color resist to be the material of the color filter 300 of each color is first formed on the entire surface. Next, exposure is performed on the color resist via a photomask, followed by development to form a resist pattern. Next, with the resist pattern being used as the mask, the color filter 300 of each color is subjected to patterning by dry etching, for example.

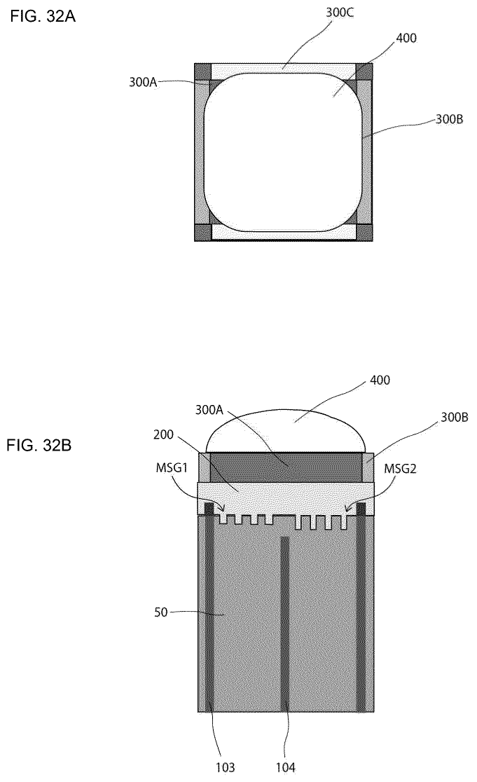

In the final step S12, the microlens 400 is formed (see the plan view of FIG. 32A and the cross-sectional view of FIG. 32B). Specifically, the microlens 400 is formed on the color filter 300 of each color by a melting method or an etch-back method.

### <<Effects of Solid-State Imaging Device>>

According to the solid-state imaging device 8, effects similar to those of the solid-state imaging device 1 according to Example 1 are obtained, and the first phase imparting structure 101a has the first microstructure group MSG1 and the second phase imparting structure 101b has the second microstructure group MSG2, so that each phase imparting structure can have both a phase imparting function and an antireflection function.

### 9. Solid-State Imaging Device According to Example 9 of an Embodiment of the Present Technology

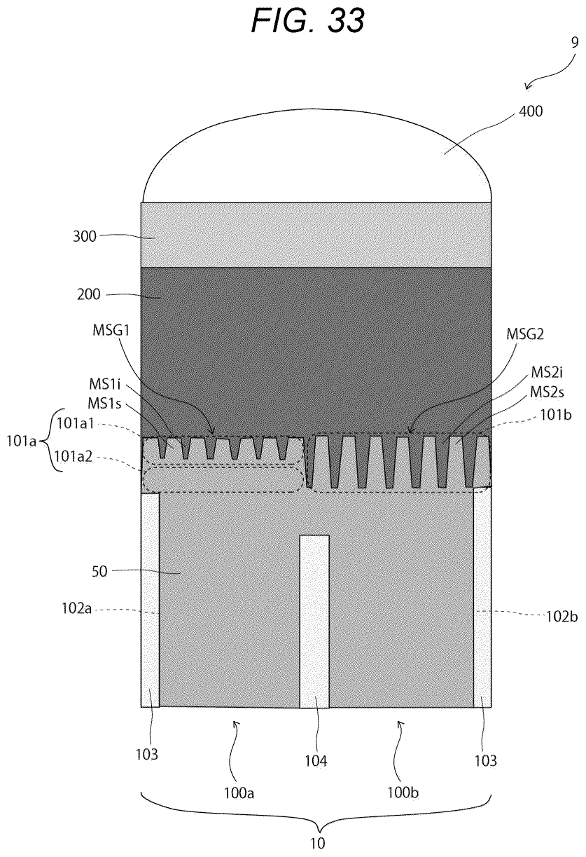

FIG. 33 is a diagram schematically illustrating a cross-sectional configuration of a solid-state imaging device 9 according to Example 9 of an embodiment of the present technology.

As illustrated in FIG. 33, the solid-state imaging device 9 has a configuration substantially similar to that of the solid-state imaging device 8 according to Example 8 except that the longitudinal sections of the first and second microstructures MS1 and MS2 have a tapered shape.

In the solid-state imaging device 9, the first type of first microstructure MS1s formed on the semiconductor substrate 50 has a forward tapered shape, and the second type of second microstructure MS1i formed on the insulating film 200 has a reverse tapered shape. That is, the plurality of first-type first microstructures MS1s constitutes a moth-eye structure as a whole. Therefore, the antireflection effect by the first and second phase imparting structures 101a and 101b can be increased.

### 10. Solid-State Imaging Device According to Example 10 of an Embodiment of the Present Technology

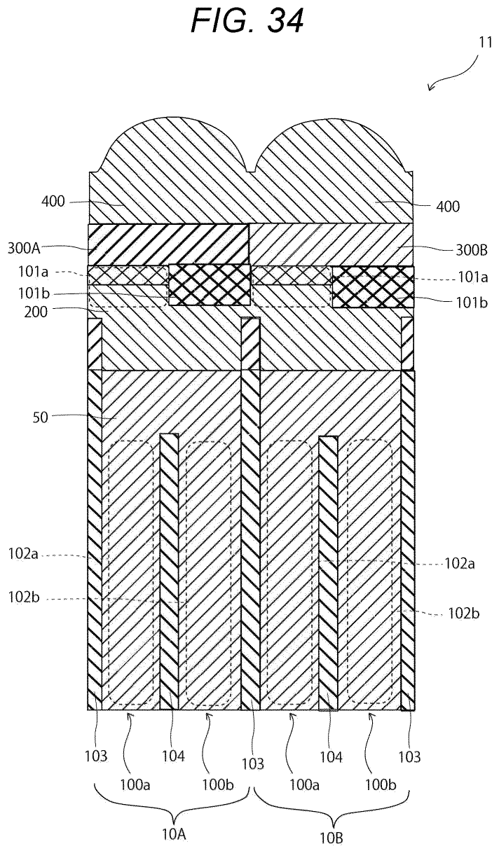

FIG. 34 is a diagram schematically illustrating a cross-sectional configuration of a solid-state imaging device 11 according to Example 10 of an embodiment of the present technology.

As illustrated in FIG. 34, the solid-state imaging device 11 has a configuration substantially similar to that of the solid-state imaging device 1 according to Example 1 except that the insulating film 200 is disposed between the first and second phase imparting structures 101a and 101b and the semiconductor substrate 50.

Also in the solid-state imaging device 11, it is preferable that the similar expressions as any of the above expressions (1) to (4) are satisfied. However, in the above Expressions (1) to (4), it is necessary to replace the refractive index of the semiconductor substrate 50 with the refractive index of the insulating film 200. In the solid-state imaging device 11, the first and second phase imparting structures 101a and 101b can be arranged similarly to the solid-state imaging device 2 according to Example 2. In this case, it is preferable that the similar expressions as any of the above Expressions (11) to (14) are satisfied. However, in the above Expressions (11) to (14), it is necessary to replace the refractive index of the insulating film 200 with the refractive index of the color filter 300. In the solid-state imaging device 11, the first and second phase imparting structures 101a and 101b can be arranged similarly to the solid-state imaging device 3 according to Example 3. In this case, it is preferable that the similar expressions as any of the above Expressions (15) to (18) are satisfied. However, in the above Expressions (15) to (18), it is necessary to replace the refractive index of the semiconductor substrate 50 with the refractive index of the insulating film 200 and replace the refractive index of the insulating film 200 with the refractive index of the color filter 300.

According to the solid-state imaging device 11, since the distance between the first and second phase imparting structures 101a and 101b and the intra-pixel separation wall 104 can be increased, it is possible to prevent light via each phase imparting structure from entering the upper portion of the intra-pixel separation wall 104 even in a case where the distance between the upper surface of the semiconductor substrate 50 and the upper portion of the intra-pixel separation wall 104 is small. Note that the intra-pixel separation wall 104 may extend from the lower surface to the upper surface of the semiconductor substrate 50.

Note that, in the solid-state imaging device 11, the antireflection structure 500 may be provided between the first and second phase imparting structures 101a and 101b and the color filter 300.

### 11. Solid-State Imaging Device According to Example 11 of an Embodiment of the Present Technology

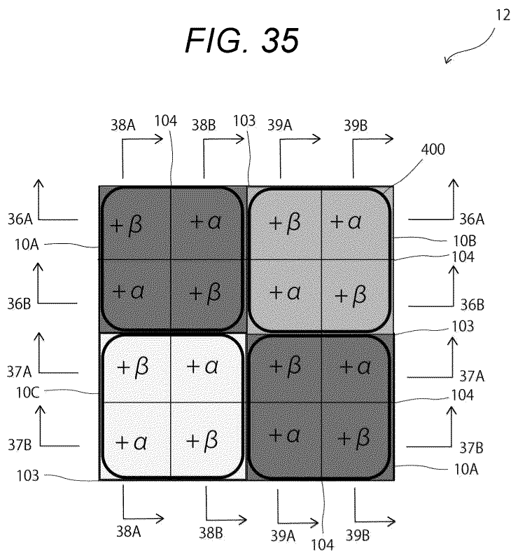

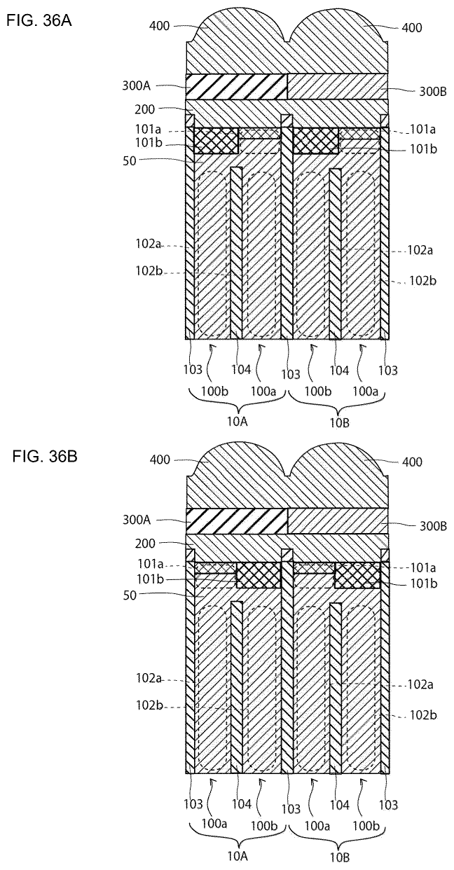

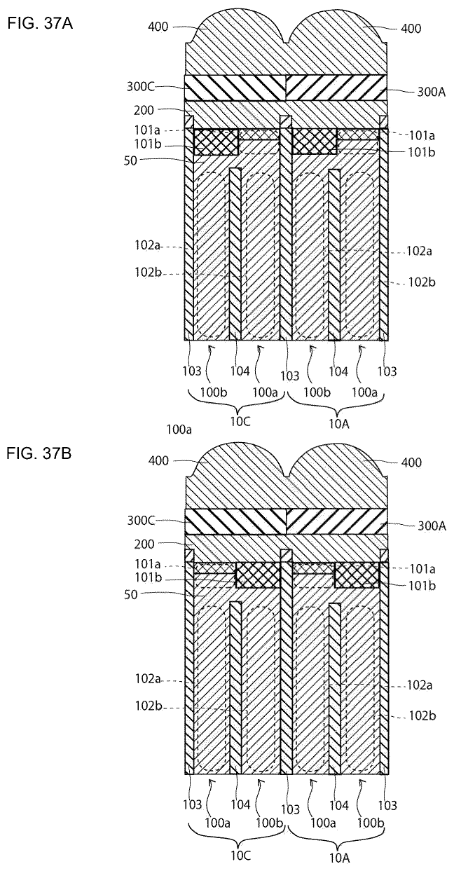

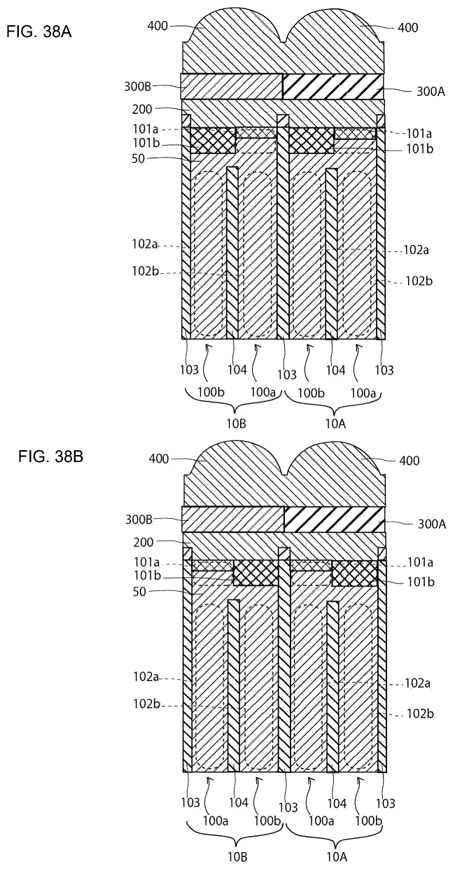

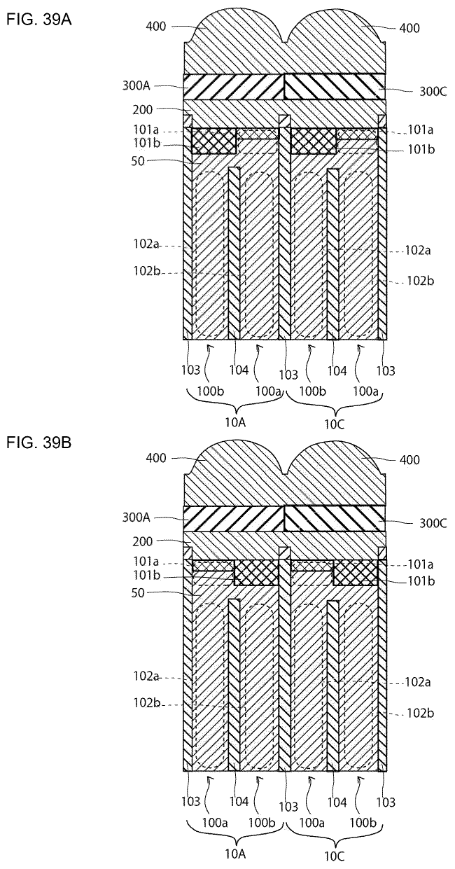

FIG. 35 is a diagram schematically illustrating a cross-sectional configuration of a solid-state imaging device 12 according to Example 11 of an embodiment of the present technology. FIG. 36A is a diagram schematically illustrating a cross section taken along line 36A-36A in FIG. 35. FIG. 36B is a diagram schematically illustrating a cross section taken along line 36B-36B in FIG. 35. FIG. 37A is a diagram schematically illustrating a cross section taken along line 37A-37A in FIG. 35. FIG. 37B is a diagram schematically illustrating a cross section taken along line 37B-37B in FIG. 35. FIG. 38A is a diagram schematically illustrating a cross section taken along line 38A-38A in FIG. 35. FIG. 38B is a diagram schematically illustrating a cross section taken along line 38B-38B in FIG. 35. FIG. 39A is a diagram schematically illustrating a cross section taken along line 39A-39A in FIG. 35. FIG. 39B is a diagram schematically illustrating a cross section taken along line 39B-39B in FIG. 35.

As illustrated in FIGS. 35 to 39B, the solid-state imaging device 12 has a configuration substantially similar to that of the solid-state imaging device 7 according to Example 7 except that the first and second light receiving units 100a are alternately arranged in the first direction (for example, in the direction of line 36A-36A in FIG. 35; the lateral direction) and the second direction (for example, the direction of line 38A-38A in FIG. 35; the longitudinal direction) orthogonal to each other in the plane in each pixel 10.

In the solid-state imaging device 12, in each pixel 10, the phase difference detection corresponding to the first direction can be performed on the basis of the outputs of the first and second light receiving units 100a and 100b arranged in the first direction (for example, the lateral direction in FIG. 35), and the phase difference detection corresponding to the second direction can be performed on the basis of the outputs of the first and second light receiving units 100a and 100b arranged in the second direction (for example, the longitudinal direction in FIG. 35).

In the solid-state imaging device 12, an inter-pixel separation wall 103 is provided between two pixels 10 vertically and horizontally adjacent to each other. Each pixel 10 includes two first and second light receiving units 100a and 100b. In each pixel 10, the intra-pixel separation wall 104 is provided between the first and second light receiving units 100a and 100b vertically and horizontally adjacent to each other. One microlens 400 is provided in common for the two first light receiving units 100a and the two second light receiving units 100b in each pixel 10. Note that the arrangement of the first and second light receiving units 100a and 100b in each pixel 10 may be opposite to the arrangement in FIG. 35.

According to the solid-state imaging device 12, since the first and second light receiving units 100a and 100b are alternately arranged in each pixel 10, the phase difference detection corresponding to the first and second directions can be performed with high accuracy.

### 12. Solid-State Imaging Device According to Example 12 of an Embodiment of the Present Technology

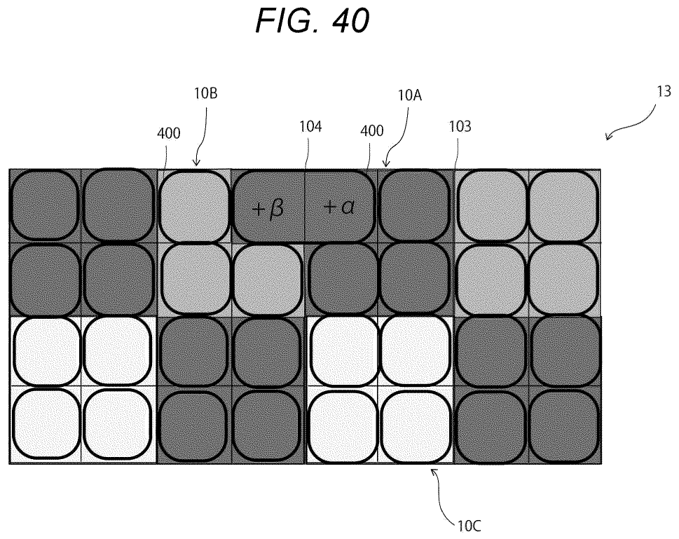

FIG. 40 is a diagram schematically illustrating a cross-sectional configuration of a solid-state imaging device 13 according to Example 12 of an embodiment of the present technology.

As an example, as illustrated in FIG. 40, the solid-state imaging device 13 has pixels arranged in a Bayer array, and all the pixels 10 excluding some (for example, two) pixels 10 (for example, pixels 10A and 10B adjacent to each other) have four light receiving units partitioned in a matrix by the intra-pixel separation wall 104 in a square region. The microlens 400 is individually provided in each of the four light receiving units. The part of the pixels 10 includes, for example, a pixel 10A having five light receiving units and, for example, a pixel 10B having three light receiving units. Only the pixel 10A having the five light receiving units has the first and second light receiving units 100a and 100b adjacent to each other. The pixel 10A includes three light receiving units in addition to the first and second light receiving units 100a and 100b. Here, the second light receiving unit 100b having the second phase imparting structure 101b that imparts the phase β to the incident light is arranged in the square region in which the three light receiving units of the pixel 10A are arranged, and the first light receiving unit 100a having the first phase imparting structure 101a that imparts the phase α to the incident light is arranged at a position adjacent to the second light receiving unit 100b in the square region in which the three light receiving units of the pixel 10A are arranged. The first and second light receiving units 100a and 100b are provided with a common microlens 400. Note that the positional relationship between the first and second light receiving units 100a and 100b may be opposite to the above description.

As described above, in addition to the pixel 10 including the first and second light receiving units 100a and 100b, the solid-state imaging device 13 includes a large number of other pixels (pixels that are not dual pixels) that are adjacent to each other and include a plurality of light receiving units that receives light in the same wavelength band. In this case, since the number of pixels 10 having the first and second phase imparting structures 101a and 101b can be reduced, the manufacturing process can be simplified.

### 13. Solid-State Imaging Device According to Example 13 of an Embodiment of the Present Technology

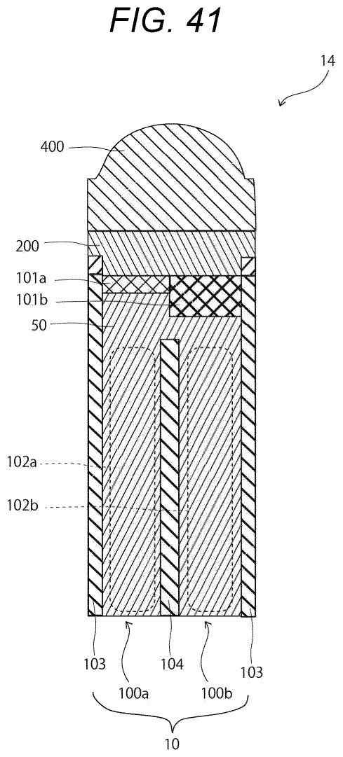

FIG. 41 is a diagram schematically illustrating a cross-sectional configuration of a solid-state imaging device 14 according to Example 13 of an embodiment of the present technology.

The solid-state imaging device 14 has a single pixel structure having a single pixel 10. Here, the solid-state imaging device 14 does not include the color filter 300, but may include the color filter. The solid-state imaging device 14 can capture an image of a subject by combining with, for example, a digital mirror device (DMD) or the like.

### 14. Solid-State Imaging Device According to Example 14 of an Embodiment of the Present Technology

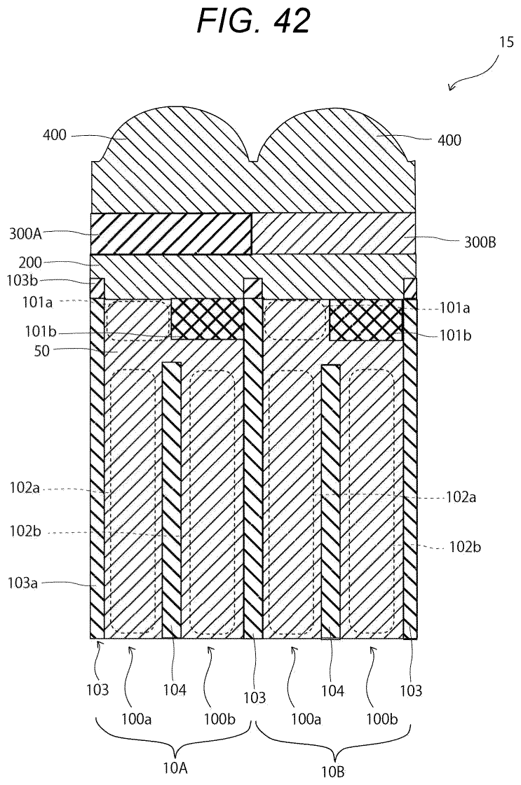

FIG. 42 is a diagram schematically illustrating a cross-sectional configuration of a solid-state imaging device 15 according to Example 14 of an embodiment of the present technology.

The solid-state imaging device 15 has a configuration substantially similar to that of that of the solid-state imaging device 1 according to Example 1 except that in each pixel 10, the first phase imparting structure 101a includes only a part of the surface layer on the light incident side of the semiconductor substrate 50.

Also in the solid-state imaging device 15, it is preferable that any one of the above Expressions (1) to (4) (where d₁=0) and/or Expressions (8) to (10) be satisfied.

According to the solid-state imaging device 15, since the first phase imparting structure 101a is substantially a part of the semiconductor substrate 50, the manufacturing process can be simplified.

### 15. Solid-State Imaging Device According to Example 15 of an Embodiment of the Present Technology

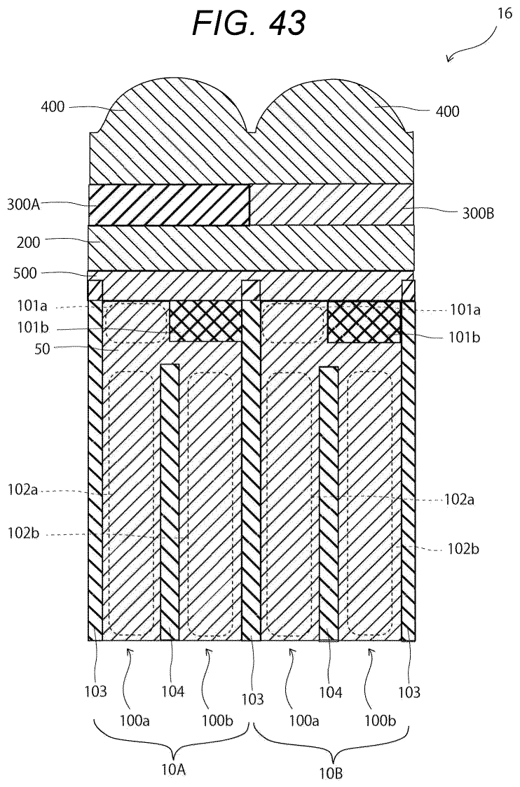

FIG. 43 is a diagram schematically illustrating a cross-sectional configuration of a solid-state imaging device 16 according to Example 15 of an embodiment of the present technology.

The solid-state imaging device 16 has a configuration substantially similar to that of the solid-state imaging device 15 according to Example 14 except that the antireflection structure 500 is provided between the first and second phase imparting structures 101a and 101b and the insulating film 200.

Also in the solid-state imaging device 16, it is preferable that any one of the above Expressions (1) to (4) (where d₁=0) and/or Expressions (8) to (10) be satisfied.

According to the solid-state imaging device 16, reflection of light on the surface of the semiconductor substrate 50 on the light incident side can be suppressed as compared with the solid-state imaging device 15 according to Example 15.

### 16. Modifications of the Present Technology

The configurations of the solid-state imaging devices of the respective examples described above can be changed as appropriate.

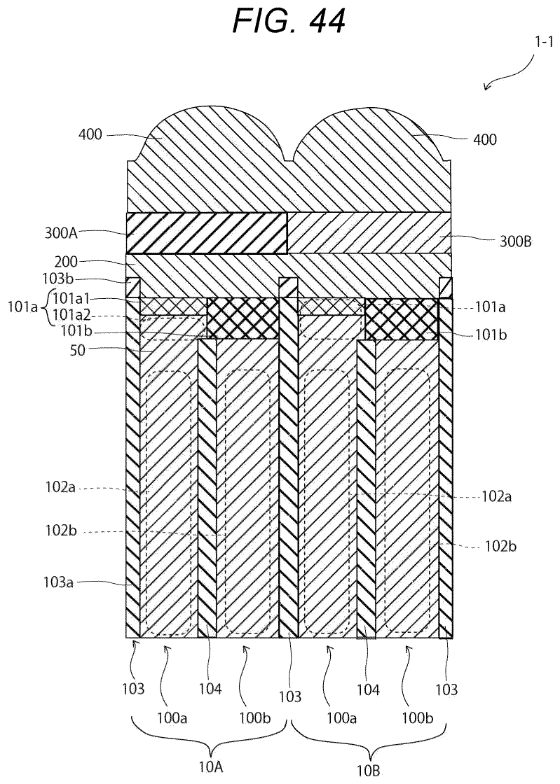

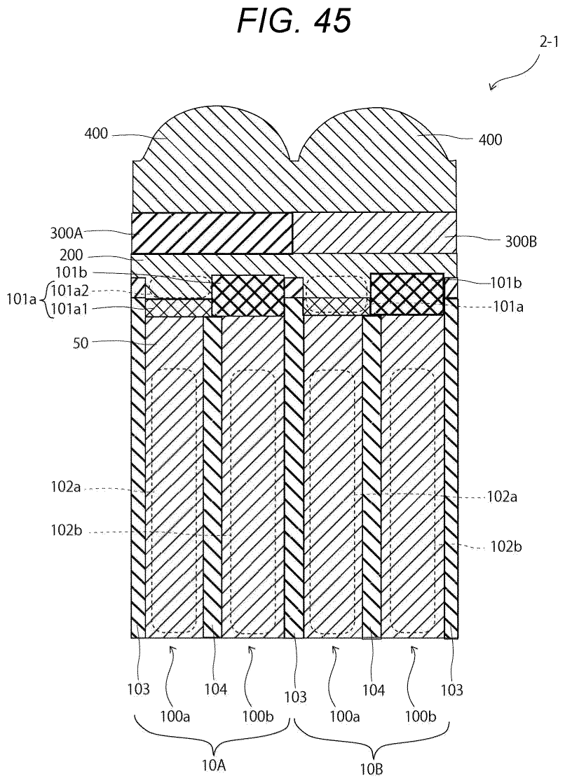

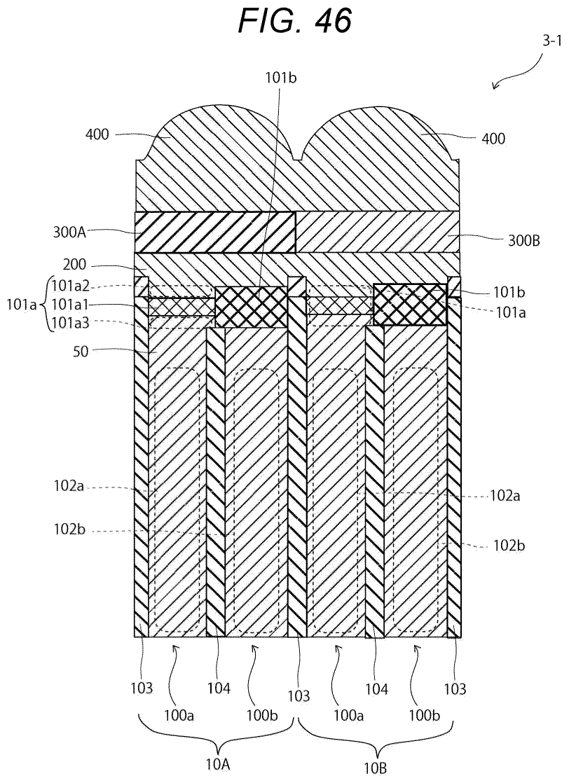

In each of the above embodiments, the intra-pixel separation wall 104 is not in contact with any of the first and second phase imparting structures 101a and 101b. However, for example, the intra-pixel separation wall 104 may be in contact with at least one of the first or second phase imparting structure 101a or 101b as in a solid-state imaging device 1-1 according to a modification of Example 1 illustrated in FIG. 44, a solid-state imaging device 2-1 according to a modification of Example 2 illustrated in FIG. 45, and a solid-state imaging device 3-1 according to a modification of Example 3 illustrated in FIG. 46. More specifically, in the solid-state imaging device 1-1 and the solid-state imaging device 3-1, the intra-pixel separation wall 104 is in contact with the second phase imparting structure 101b. In the solid-state imaging device 2-1, the intra-pixel separation wall 104 is in contact with both the first and second phase imparting structures 101a and 101b.

The pixel array of the solid-state imaging device according to the present technology is not limited to the Bayer array, and may be another array.

A solid-state imaging device may not include at least one of the color filter 300 or the microlens 400 for example. In a case where the solid-state imaging device is used to generate a black-and-white image, for example, the color filter 300 may not be provided. In a case where the solid-state imaging device is used for sensing such as distance measurement, for example, at least one of the color filter 300 or the microlens 400 may not be provided.

For example, the configurations of the solid-state imaging devices of the above-described embodiments and modifications may be combined with each other within a range that is not technically contradictory.

The numerical values, materials, shapes, dimensions, and the like used in the description of the above respective Examples and modifications are merely examples, and do not limit the present technology.

### 17. Usage Example of Solid-State Imaging Device to which the Present Technology is Applied

FIG. 46 is a diagram illustrating usage examples in a case where a solid-state imaging device according to the present technology (for example, a solid-state imaging device according to each of Examples and the modifications) forms a solid-state imaging device (an image sensor).

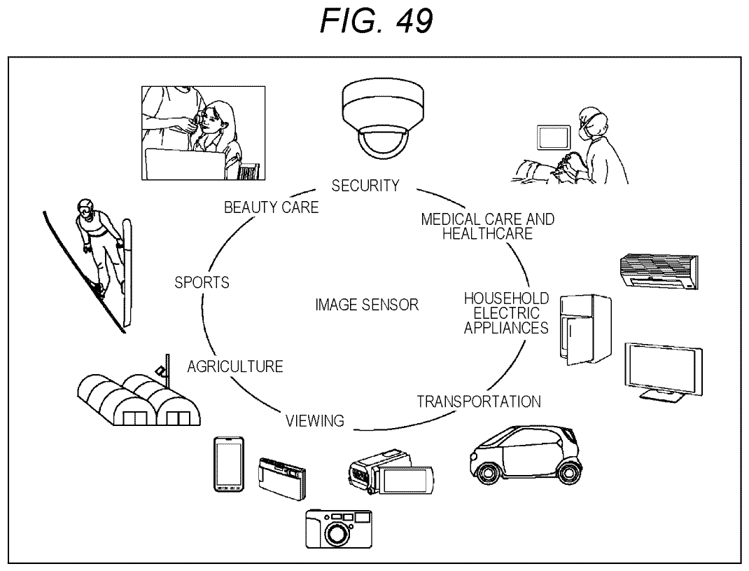

The respective Examples and modifications described above can be used in various cases of sensing light such as visible light, infrared light, ultraviolet light, and an X-ray as described below, for example. That is, as illustrated in FIG. 49, the above Examples and modifications can be used for devices that are used in the field of viewing in which images for viewing are captured, the field of transportation, the field of household electric appliances, the field of medical care and healthcare, the field of security, the field of beauty care, the field of sports, the field of agriculture, and the like, for example.

Specifically, in the field of viewing, a solid-state imaging device according to the present technology can be used for a device for capturing an image to be viewed, such as a digital camera, a smartphone, and a mobile phone with a camera function, for example.

In the field of transportation, for example, for safe driving such as automatic stop, recognition of a state of the driver, and the like, a solid-state imaging device according to the present technology can be used for a device to be used for transportation, such as a vehicle-mounted sensor that captures an image in the front, the rear, the surroundings, the interior, and the like of an automobile, a monitoring camera that monitors traveling vehicles and roads, or a distance measurement sensor that measures distance between vehicles.

In the field of household electric appliances, to capture an image of a user's gesture and operate a device in accordance with the gesture, for example, a solid-state imaging device according to the present technology can be used for a device that is used in household electric appliances such as a TV receiver, a refrigerator, and an air conditioner.

In the field of medical care and healthcare, for example, a solid-state imaging device according to the present technology can be used for a device that is used for medical care and healthcare, such as an endoscope or a device that performs angiography by receiving infrared light.

In the field of security, for example, a solid-state imaging device according to the present technology can be used for a device that is used for security, such as a monitoring camera for crime prevention or a camera for person authentication.

In the field of beauty care, for example, a solid-state imaging device according to the present technology can be used for a device that is used for beauty care, such as a skin measuring instrument for capturing an image of the skin or a microscope for capturing an image of the scalp.

In the field of sports, for example, a solid-state imaging device according to the present technology can be used for a device that is used for sports, such as an action camera or a wearable camera for the use in sports and the like.

In the field of agriculture, for example, a solid-state imaging device according to the present technology can be used for a device that is used for agriculture, such as a camera for monitoring a condition of fields and crops.

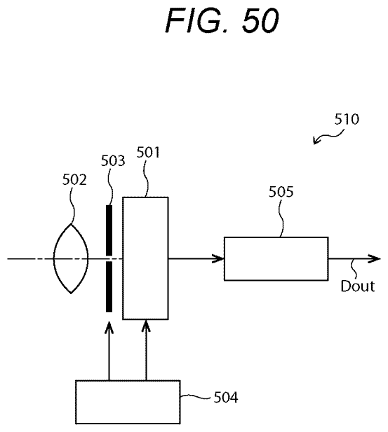

Next, usage examples of a solid-state imaging device according to the present technology (for example, a solid-state imaging device according to each of Examples and modifications) are specifically described. For example, the solid-state imaging device according to each of Examples and the modifications described above can be applied as a solid-state imaging device 501 to an electronic apparatus of any type that has an imaging function, such as the camera system of a digital still camera, a video camera, or the like, or a mobile phone having an imaging function, for example. FIG. 50 illustrates a schematic configuration of an electronic apparatus 510 (camera) as an example. The electronic apparatus 510 is a video camera capable of taking a still image or a moving image, for example, and includes the solid-state imaging device 501, an optical system (optical lens) 502, a shutter device 503, a drive unit 504 that drives the solid-state imaging device 501 and the shutter device 503, and a signal processing unit 505.

The optical system 502 guides image light (incident light) from a subject to a pixel region of the solid-state imaging device 501. The optical system 502 may include a plurality of optical lenses. The shutter device 503 controls a light irradiation period and a light shielding period regarding the solid-state imaging device 501. The drive unit 504 controls a transfer operation of the solid-state imaging device 501 and a shutter operation of the shutter device 503. The signal processing unit 505 performs various types of signal processing on a signal output from the solid-state imaging device 501. A video signal Dout after the signal processing is stored in a storage medium such as a memory or output to a monitor and the like.

### 18. Other Usage Examples of Solid-State Imaging Device to which the Present Technology is Applied

A solid-state imaging device according to the present technology (a solid-state imaging device according to each example and each modification, for example) can also be applied to some other electronic apparatus that detects light, such as a time of flight (TOF) sensor, for example. In a case where the solid-state imaging device is applied to a TOF sensor, for example, the solid-state imaging device can be applied to a distance image sensor by a direct TOF measurement method, or a distance image sensor by an indirect TOF measurement method. In the distance image sensor by the direct TOF measurement method, arrival timing of photons is directly obtained in a time domain in each pixel. Therefore, a light pulse having a short pulse width is transmitted, and an electrical pulse is generated by a receiver that responds at a high speed. The present disclosure can be applied to the receiver at that time. Furthermore, by the indirect TOF method, a flight time of light is measured with a semiconductor element structure in which detection and an accumulation amount of carriers generated by light change depending on the arrival timing of light. The present disclosure can also be applied to such a semiconductor structure. In the case of application to a TOF sensor, a color filter and a microlens as illustrated in FIG. 1 and others are optionally provided, and these layers may not be provided.

### 19. Application Example to Mobile Body

The technology of the present disclosure (present technology) can be applied to various products. For example, the technology of the present disclosure may be achieved in the form of a device to be installed on a mobile object of any kind, such as an automobile, an electric vehicle, a hybrid electric vehicle, a motorcycle, a bicycle, a personal mobility, an airplane, a drone, a vessel, or a robot.

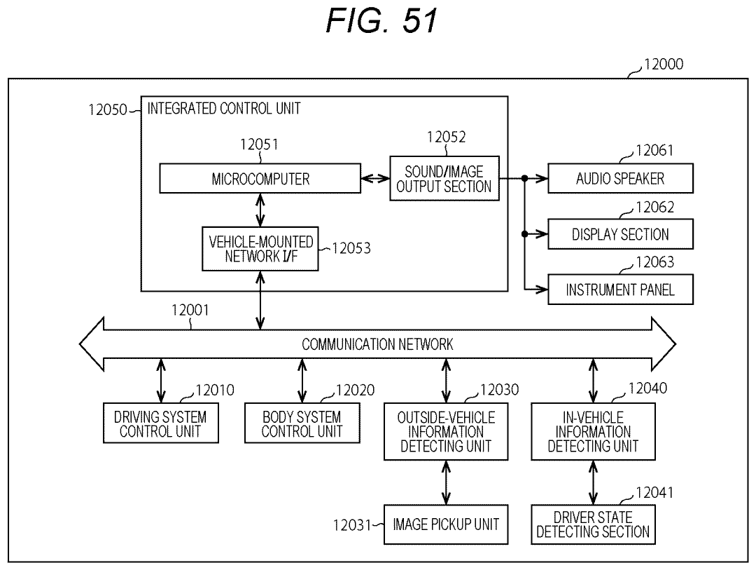

FIG. 51 is a block diagram illustrating a schematic configuration example of a vehicle control system as an example of a mobile body control system to which the technology of the present disclosure is applied.

A vehicle control system 12000 includes a plurality of electronic control units connected to each other via a communication network 12001. In the example illustrated in FIG. 51, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an image pickup unit 12031. The outside-vehicle information detecting unit 12030 makes the image pickup unit 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The image pickup unit 12031 is an optical sensor that receives light, and which outputs an electric signal corresponding to a received light amount of the light. The image pickup unit 12031 can output the electric signal as an image, or can output the electric signal as information about a measured distance. Furthermore, the light received by the image pickup unit 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate the degree of fatigue of the driver or the degree of concentration of the driver or may determine whether the driver is awake.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a lane deviation warning of the vehicle, or the like.

Furthermore, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent glare by controlling the headlamp so as to switch from a high beam to a low beam or the like, for example, according to the position of a preceding vehicle or an oncoming vehicle detected by the outside-vehicle information detecting unit 12030.

The sound/image output section 12052 transmits an output signal of at least one of a sound or an image to an output device capable of visually or auditorily notifying information to an occupant of the vehicle or the outside of the vehicle. In the example of FIG. 51, an audio speaker 12061, a display section 12062, and an instrument panel 12063 are illustrated as the output device. The display section 12062 may, for example, include at least one of an on-board display or a head-up display.

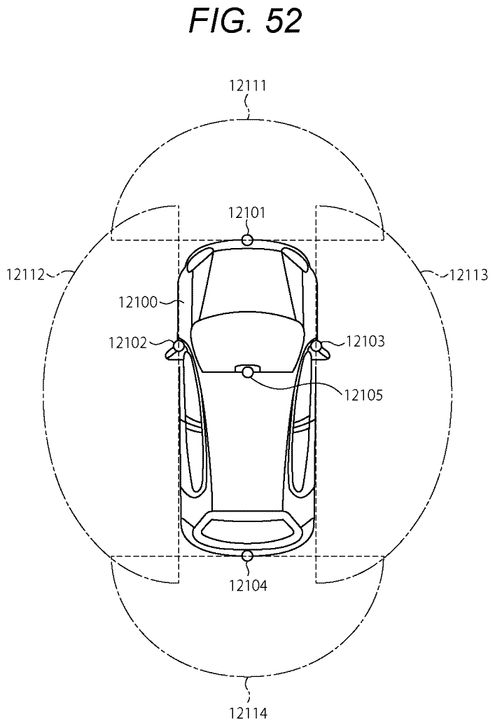

FIG. 52 is a diagram depicting an example of the installation position of the image pickup unit 12031.

In FIG. 52, a vehicle 12100 includes image pickup units 12101, 12102, 12103, 12104, and 12105, as the image pickup unit 12031.

The image pickup units 12101, 12102, 12103, 12104, and 12105 are provided, for example, at positions such as a front nose, a sideview mirror, a rear bumper, a back door, and an upper portion of a windshield in the interior of the vehicle 12100. The image pickup unit 12101 provided to the front nose and the image pickup unit 12105 provided to the upper portion of the windshield within the interior of the vehicle obtain mainly an image of the front of the vehicle 12100. The image pickup units 12102 and 12103 provided to the sideview mirrors obtain mainly an image of the sides of the vehicle 12100. The image pickup unit 12104 provided to the rear bumper or the back door obtains mainly an image of the rear of the vehicle 12100. The forward images obtained by the image pickup units 12101 and 12105 are used mainly to detect a preceding vehicle, a pedestrian, an obstacle, a traffic signal, a traffic sign, a lane, or the like.

Note that FIG. 52 illustrates an example of imaging ranges of the image pickup units 12101 to 12104. An imaging range 12111 represents the imaging range of the image pickup unit 12101 provided to the front nose. Imaging ranges 12112 and 12113 respectively represent the imaging ranges of the image pickup units 12102 and 12103 provided to the sideview mirrors. An imaging range 12114 represents the imaging range of the image pickup unit 12104 provided to the rear bumper or the back door. A bird's-eye image of the vehicle 12100 as viewed from above is obtained by superimposing image data imaged by the image pickup units 12101 to 12104, for example.

At least one of the image pickup units 12101 to 12104 may have a function of obtaining distance information. For example, at least one of the image pickup units 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the image pickup units 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Moreover, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the image pickup units 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the image pickup units 12101 to 12104 may be an infrared camera that detects infrared rays. The microcomputer 12051 can, for example, recognize a pedestrian by determining whether or not there is a pedestrian in imaged images of the image pickup units 12101 to 12104. Such recognition of a pedestrian is, for example, performed by a procedure of extracting characteristic points in the imaged images of the image pickup units 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the image pickup units 12101 to 12104, and thus recognizes the pedestrian, the sound/image output section 12052 controls the display section 12062 so that a square contour line for emphasis is displayed so as to be superimposed on the recognized pedestrian. Furthermore, the sound/image output section 12052 may also control the display section 12062 so that an icon or the like representing the pedestrian is displayed at a desired position.

An example of the vehicle control system to which the technology according to the present disclosure (present technology) can be applied has been described above. The technology according to the present disclosure can be applied to the image pickup unit 12031 and the like, for example, out of the configurations described above. Specifically, for example, the solid-state imaging device 111 of the present disclosure can be applied to the image pickup unit 12031. By applying the technology according to the present disclosure to the image pickup unit 12031, it is possible to improve yield and reduce cost related to manufacturing.

### 11. Application Example to Endoscopic Surgery System

The present technology can be applied to various products. For example, the technology according to the present disclosure (present technology) may be applied to an endoscopic surgery system.

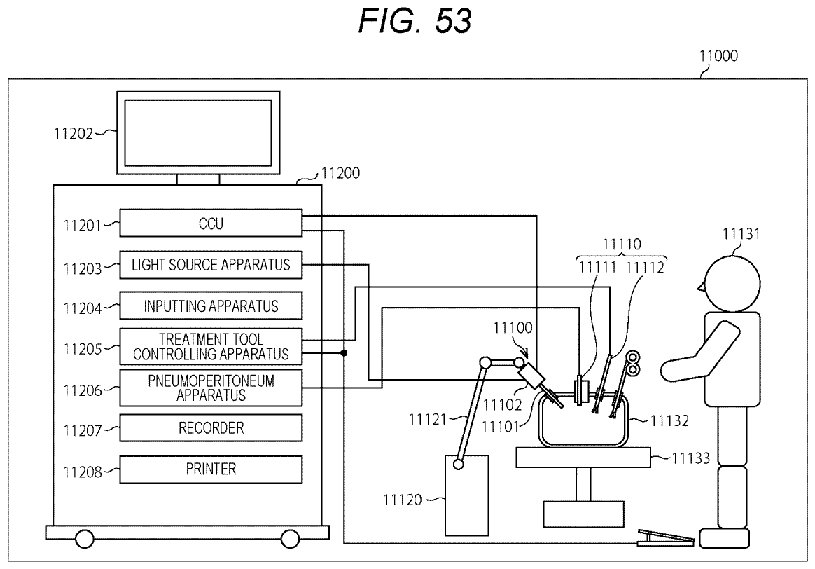

FIG. 53 is a diagram illustrating an example of a schematic configuration of an endoscopic surgery system to which the technology according to an embodiment of the present disclosure (present technology) can be applied.

In FIG. 53, a state is depicted in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101.

In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. Note that it is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a camera control unit (CCU) 11201.

The CCU 11201 includes a central processing unit (CPU), a graphics processing unit (GPU) or the like and integrally controls operation of the endoscope 11100 and a display apparatus 11202. Moreover, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

Note that it is to be noted that the light source apparatus 11203 which supplies irradiation light when a surgical region is to be imaged to the endoscope 11100 may include a white light source which includes, for example, an LED, a laser light source or a combination of them. In a case where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Furthermore, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Furthermore, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Furthermore, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

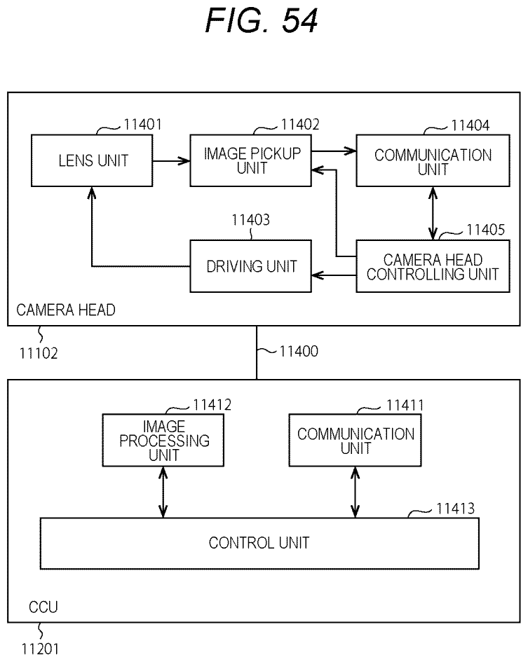

FIG. 54 is a block diagram illustrating an example of a functional configuration of the camera head 11102 and the CCU 11201 illustrated in FIG. 53.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). In a case where the image pickup unit 11402 is configured as that of the multi-plate type, for example, image signals corresponding to respective R, G and B are generated by the image pickup elements, and the image signals may be synthesized to obtain a color image. Alternatively, the image pickup unit 11402 may include a pair of image pickup elements for acquiring right-eye and left-eye image signals corresponding to three-dimensional (3D) display. If 3D display is performed, then the depth of a living body tissue in a surgical region can be comprehended more accurately by the surgeon 11131. Note that it is to be noted that, in a case where the image pickup unit 11402 is configured as that of stereoscopic type, a plurality of systems of lens units 11401 is provided corresponding to the individual image pickup elements.

Furthermore, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

Furthermore, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

Note that it is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Furthermore, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Furthermore, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be applied to the endoscope 11100, (the image pickup unit 11402 of) the camera head 11102, and the like out of the configurations described above. Specifically, the solid-state imaging device 111 of the present disclosure can be applied to the image pickup unit 10402. By applying the technology according to the present disclosure to the endoscope 11100, (the image pickup unit 11402 of) the camera head 11102, and the like, it is possible to improve yield and reduce cost related to manufacturing.

Here, the endoscopic surgery system has been described as an example, but the technology according to the present disclosure may be applied to other, for example, a microscopic surgery system or the like.

Furthermore, the present technology may also adopt the following configurations.
(1) The solid-state imaging device, including:
a pixel that includes:
first and second light receiving units that are adjacent to each other and receive light in a same wavelength band; and
a separation wall provided between the first and second light receiving units, in which
the first light receiving unit includes:
a first photoelectric conversion element; and
a first phase imparting structure that is provided on an incident side of the light of the first photoelectric conversion element and imparts a first phase to incident light, and
the second light receiving unit includes:
a second photoelectric conversion element; and
a second phase imparting structure that is provided on an incident side of the light of the second photoelectric conversion element and imparts a second phase different from the first phase to incident light.
(2) The solid-state imaging device according to (1), in which
the separation wall is provided at least between the first and second photoelectric conversion elements, and
the first and second phase imparting structures are located on an incident side of the light of the separation wall.
(3) The solid-state imaging device according to (1) or (2), in which
an absolute value of a phase difference between the first and second phases is a value of (Nπ−π/2) or more and (Nπ+π/2) or less, where N is an odd number.
(4) The solid-state imaging device according to any one of (1) to (3), in which
the first and second photoelectric conversion elements are provided side by side in a semiconductor substrate, and
the first phase imparting structure includes:
a first portion that is a portion having a refractive index different from a refractive index of the semiconductor substrate and is provided on a surface of the semiconductor substrate on an incident side of the light; and
a second portion that is a part of the semiconductor substrate and is located on a side opposite to an incident side of the light of the first portion,
the second phase imparting structure is provided on a surface of the semiconductor substrate on an incident side of the light, and
surfaces of the first portion and the second phase imparting structure on an incident side of the light are flush.
(5) The solid-state imaging device according to (4), in which
with respect to a refractive index n₁ and a thickness d₁ of the first portion, a refractive index n₂ and a thickness d₂ (≥d₁) of the second phase imparting structure, a refractive index nₛ of the semiconductor substrate, and a wavelength λ of the light, (Nλ/2−λ/4)≤|n₁d₁+n₃(d₂−d₁)−n₂d₂|≤(Nλ/2+λ/4) is satisfied, where N is an odd number.
(6) The solid-state imaging device according to any one of (1) to (3), in which
the first and second photoelectric conversion elements are provided side by side in a semiconductor substrate,
an insulating film is provided on an incident side of the light of the semiconductor substrate,
the first phase imparting structure includes:
a first portion that is a portion having a refractive index different from a refractive index of the insulating film and is provided on a surface of the semiconductor substrate on an incident side of the light; and
a second portion that is a part of the insulating film and is located on an incident side of the light of the first portion,
the second phase imparting structure is provided between the semiconductor substrate and the insulating film, and
surfaces of the first portion and the second phase imparting structure on a side opposite to an incident side of the light are flush.
(7) The solid-state imaging device according to (6), in which
with respect to a refractive index n₁ and a thickness d₁ of the first portion, a refractive index n₂ and a thickness d₂ (≥d₁) of the second phase imparting structure, a refractive index n₁ of the insulating film, and a wavelength λ of the light, (Nλ/2−λ/4)≤|n₁d₁+n₁ (d₂−d₁)−n₂d₂|≤(Nλ/2+λ/4) is satisfied, where N is an odd number.
(8) The solid-state imaging device according to any one of (1) to (7), in which
the first phase imparting structure has a plurality of first microstructures, and
the second phase imparting structure has a plurality of second microstructures.
(9) The solid-state imaging device according to (8), in which
the plurality of first microstructures includes first and second types of first microstructures having different refractive indexes, the first and second types of first microstructures being alternately arranged in an in-plane direction, and
the plurality of second microstructures includes first and second types of second microstructures having different refractive indexes, the first and second types of second microstructures being alternately arranged in an in-plane direction.
(10) The solid-state imaging device according to (9), in which
a ratio of a sum of volumes of the first type of first microstructures and a sum of volumes of the second type of first microstructures is different from a ratio of a sum of volumes of the first type of second microstructures and a sum of volumes of the second type of second microstructures.
(11) The solid-state imaging device according to any one of (8) to (10), in which
a longitudinal section of at least one of the first or second microstructure has a tapered shape.
(12) The solid-state imaging device according to any one of (1) to (11), in which
at least one of the first or second phase imparting structure has an antireflection function of preventing reflection of the light.
(13) The solid-state imaging device according to (1) to (12), in which
the pixel includes an antireflection structure that is arranged on an incident side of the light of the first and second phase imparting structures and prevents reflection of the light.
(14) The solid-state imaging device according to any one of (1) to (13), in which
light receiving areas of the first and second light receiving units are different.
(15) The solid-state imaging device according to any one of (1) to (14), in which
the first and second photoelectric conversion elements are provided side by side in a semiconductor substrate, and
the pixel includes an insulating film disposed between the first and second phase imparting structures and the semiconductor substrate.
(16) The solid-state imaging device according to any one of (1) to (15), in which
the first light receiving unit further includes the second phase imparting structure adjacent to the first phase imparting structure,
the light via the second phase imparting structure of the first light receiving unit is also incident on the first photoelectric conversion element,
the second light receiving unit further includes the first phase imparting structure adjacent to the second phase imparting structure,
the light via the first phase imparting structure of the second light receiving unit is also incident on the second photoelectric conversion element, and
in the pixel, the first and second phase imparting structures are alternately arranged with respect to first and second directions orthogonal to each other in a plane.
(17) The solid-state imaging device according to any one of (1) to (16), in which
the pixel includes a plurality of the first and second light receiving units, and
in the pixel, the first and second light receiving units are alternately arranged in first and second directions orthogonal to each other in a plane.
(18) The solid-state imaging device according to any one of (1) to (17), further including:
other pixels that are adjacent to each other and include a plurality of light receiving units that receives light in a same wavelength band.
(19) The solid-state imaging device according to any one of (1) to (18), in which
the pixel includes a color filter provided on an incident side of the light of the first and second light receiving units and having the wavelength band as a transmission wavelength band.
(20) The solid-state imaging device according to (19), in which
the pixel includes a microlens provided on an incident side of the light of the color filter.
(21) The first and second photoelectric conversion elements are provided in a semiconductor substrate, and an insulating film is provided between the first and second phase imparting structures and the semiconductor substrate. The first phase imparting structure includes a first portion that is a portion having a refractive index different from that of the semiconductor substrate and is provided on a surface of the semiconductor substrate on an incident side of the light, a second portion that is a part of the insulating film and is located on an incident side of the light of the first portion, and a third portion that is a part of the semiconductor substrate and is located on a side opposite to an incident side of the light of the first portion. The first and second phase imparting structures are not flush with both the surface on an incident side of the light and a surface on a side opposite to an incident side of the light.
(22) With respect to a refractive index n₁ and a thickness d₁ of the first portion, a refractive index n₂ and a thickness d₂ (≥d1) of the second phase imparting structure, a refractive index nₛ of a semiconductor substrate, a refractive index n₁ of the insulating film, a thickness d₁ of the second portion, a thickness dₛ of the third portion, and a wavelength λ of light, (Nλ/2−λ/4)≤|n₁d₁+nₛdₛ+n₁d₁−n₂d₂<(Nλ/2+λ/4) (where d₁+dₛ+d₁=d₂) is satisfied, where N is an odd number.
(23) An electronic apparatus including the solid-state imaging device according to any one of (1) to (22).

### REFERENCE SIGNS LIST

1, 2, 3, 4, 5, 6, 7, 8, 9, 11, 12, 13, 14, 15, 16 Solid-state imaging device
10, 10A, 10B, 10C Pixel
50 Semiconductor substrate
100a First light receiving unit
100b Second light receiving unit
101a First phase imparting structure
101b Second phase imparting structure
102a First photoelectric conversion element
102b Second photoelectric conversion element
104 Intra-pixel separation wall (separation wall)
200 Insulating film
300, 300A, 300B, 300C Color filter
400 Microlens
500 Antireflection structure
α First phase
β Second phase
MS1 First microstructure
MS1s First type of first microstructure
MS1i Second type of first microstructure
MS2 Second microstructure
MS2s First type of second microstructure
MS2i Second type of second microstructure

1. A solid-state imaging device, comprising:
a pixel that includes:
first and second light receiving units that are adjacent to each other and receive light in a same wavelength band; and
a separation wall provided between the first and second light receiving units, wherein
the first light receiving unit includes:
a first photoelectric conversion element; and
a first phase imparting structure that is provided on an incident side of the light of the first photoelectric conversion element and imparts a first phase to incident light, and
the second light receiving unit includes:
a second photoelectric conversion element; and
a second phase imparting structure that is provided on an incident side of the light of the second photoelectric conversion element and imparts a second phase different from the first phase to incident light.

2. The solid-state imaging device according to claim 1, wherein
the separation wall is provided at least between the first and second photoelectric conversion elements, and
the first and second phase imparting structures are located on an incident side of the light of the separation wall.

3. The solid-state imaging device according to claim 1, wherein
an absolute value of a phase difference between the first and second phases is a value of (Nπ−π/2) or more and (Nπ+π/2) or less, where N is an odd number.

4. The solid-state imaging device according to claim 1, wherein
the first and second photoelectric conversion elements are provided side by side in an in-plane direction in a semiconductor substrate, and
the first phase imparting structure includes:
a first portion that is a portion having a refractive index different from a refractive index of the semiconductor substrate and is provided on a surface of the semiconductor substrate on an incident side of the light; and
a second portion that is a part of the semiconductor substrate and is located on a side opposite to an incident side of the light of the first portion,
the second phase imparting structure is provided on a surface of the semiconductor substrate on an incident side of the light, and
surfaces of the first portion and the second phase imparting structure on an incident side of the light are flush.

5. The solid-state imaging device according to claim 4, wherein
with respect to a refractive index n₁ and a thickness d₁ of the first portion, a refractive index n₂ and a thickness d₂ (≥d₁) of the second phase imparting structure, a refractive index nₛ of the semiconductor substrate, and a wavelength λ of the light, (Nλ/2−λ/4)≤|n₁d₁+nₛ (d₂−d₁)−n₂d₂|≤(Nλ/2+λ/4) is satisfied, where N is an odd number.

6. The solid-state imaging device according to claim 1, wherein
the first and second photoelectric conversion elements are provided side by side in an in-plane direction in a semiconductor substrate,
an insulating film is provided on an incident side of the light of the semiconductor substrate,
the first phase imparting structure includes:
a first portion that is a portion having a refractive index different from a refractive index of the insulating film and is provided on a surface of the semiconductor substrate on an incident side of the light; and
a second portion that is a part of the insulating film and is located on an incident side of the light of the first portion,
the second phase imparting structure is provided between the semiconductor substrate and the insulating film, and
surfaces of the first portion and the second phase imparting structure on a side opposite to an incident side of the light are flush.

7. The solid-state imaging device according to claim 6, wherein
with respect to a refractive index n₁ and a thickness d₁ of the first portion, a refractive index n₂ and a thickness d₂ (≥d₁) of the second phase imparting structure, a refractive index n₁ of the insulating film, and a wavelength λ of the light, (Nλ/2−λ/4)≤|n₁d₁+n₁ (d₂−d₁)−n₂d₂|≤(Nλ/2+λ/4) is satisfied, where N is an odd number.

8. The solid-state imaging device according to claim 1, wherein
the first phase imparting structure has a plurality of first microstructures, and
the second phase imparting structure has a plurality of second microstructures.

9. The solid-state imaging device according to claim 8, wherein
the plurality of first microstructures includes first and second types of first microstructures having different refractive indexes, the first and second types of first microstructures being alternately arranged in an in-plane direction, and
the plurality of second microstructures includes first and second types of second microstructures having different refractive indexes, the first and second types of second microstructures being alternately arranged in an in-plane direction.

10. The solid-state imaging device according to claim 9, wherein
a ratio of a sum of volumes of the first type of first microstructures and a sum of volumes of the second type of first microstructures is different from a ratio of a sum of volumes of the first type of second microstructures and a sum of volumes of the second type of second microstructures.

11. The solid-state imaging device according to claim 8, wherein
a longitudinal section of at least one of the first or second microstructure has a tapered shape.

12. The solid-state imaging device according to claim 1, wherein
at least one of the first or second phase imparting structure has an antireflection function of preventing reflection of the light.

13. The solid-state imaging device according to claim 1, wherein
the pixel includes an antireflection structure that is arranged on an incident side of the light of the first and second phase imparting structures and prevents reflection of the light.

14. The solid-state imaging device according to claim 1, wherein
light receiving areas of the first and second light receiving units are different.

15. The solid-state imaging device according to claim 1, wherein
the first and second photoelectric conversion elements are provided side by side in an in-plane direction in a semiconductor substrate, and
the pixel includes an insulating film disposed between the first and second phase imparting structures and the semiconductor substrate.

16. The solid-state imaging device according to claim 1, wherein
the first light receiving unit further includes the second phase imparting structure adjacent to the first phase imparting structure,
the light via the second phase imparting structure of the first light receiving unit is also incident on the first photoelectric conversion element,
the second light receiving unit further includes the first phase imparting structure adjacent to the second phase imparting structure,
the light via the first phase imparting structure of the second light receiving unit is also incident on the second photoelectric conversion element, and
in the pixel, the first and second phase imparting structures are alternately arranged with respect to first and second directions orthogonal to each other in a plane.

17. The solid-state imaging device according to claim 1, wherein
the pixel includes a plurality of the first and second light receiving units, and
in the pixel, the first and second light receiving units are alternately arranged in first and second directions orthogonal to each other in a plane.

18. The solid-state imaging device according to claim 1, further comprising:
other pixels that are adjacent to each other and include a plurality of light receiving units that receives light in a same wavelength band.

19. The solid-state imaging device according to claim 1, wherein
the pixel includes a color filter provided on an incident side of the light of the first and second light receiving units and having the wavelength band as a transmission wavelength band.

20. The solid-state imaging device according to claim 19, wherein
the pixel includes a microlens provided on an incident side of the light of the color filter.
